(19) United States
(12) Patent Application Publication
(10) Pub. No.: US 2025/0228080 A1
(43) Pub. Date: Jul. 10, 2025

(54) DISPLAY APPARATUS AND METHOD OF FABRICATING DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Peng Hou, Beijing (CN); Jianbo Xian, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/690,054

(22) PCT Filed: May 30, 2023
(86) PCT No.: PCT/CN2023/097201

§ 371 Date: Mar. 7, 2024

(51) Int. Cl. H10K 59/124; H10K 59/12; H10K 59/131; H10K 59/40

(52) U.S. Cl. CPC H10K 59/124; H10K 59/1201; H10K 59/131; H10K 59/40

(57) ABSTRACT

A display apparatus is provided. The display apparatus a display area and a peripheral area. In the display area, the display apparatus includes a pixel driving circuit substrate, a plurality of light emitting elements on the pixel driving circuit substrate, an encapsulating layer on a side of the plurality of light emitting elements away from the pixel driving circuit substrate; and an inorganic insulating layer on a side of the encapsulating layer away from the plurality of light emitting elements. In a bonding pin region of the peripheral area, the display apparatus includes a base substrate, a plurality of bonding pins on the base substrate. An orthographic projection of the inorganic insulating layer on the base substrate is at least partially non-overlapping with an orthographic projection of the plurality of bonding pins on the base substrate.

### TECHNICAL FIELD

The present invention relates to display technology, more particularly, to a display apparatus and a method of fabricating a display apparatus.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides a display apparatus, comprising a display area and a peripheral area; wherein, in the display area, the display apparatus comprises a pixel driving circuit substrate, a plurality of light emitting elements on the pixel driving circuit substrate, an encapsulating layer on a side of the plurality of light emitting elements away from the pixel driving circuit substrate; and an inorganic insulating layer on a side of the encapsulating layer away from the plurality of light emitting elements; in a bonding pin region of the peripheral area, the display apparatus comprises a base substrate, a plurality of bonding pins on the base substrate; and an orthographic projection of the inorganic insulating layer on the base substrate is at least partially non-overlapping with an orthographic projection of the plurality of bonding pins on the base substrate.

Optionally, the display apparatus in the display area further comprises: a buffer layer on a side of the inorganic insulating layer away from the encapsulating layer; a first touch layer on a side of the buffer layer away from the inorganic insulating layer; a touch insulating layer on a side of the first touch layer away from the buffer layer; a second touch layer on a side of the touch insulating layer away from the first touch layer; and an overcoat layer on a side of the second touch layer away from the touch insulating layer; wherein the buffer layer, the touch insulating layer, and the overcoat layer are made of a polymeric organic material.

Optionally, the display apparatus, in the display area, further comprises a black matrix and a color filter on a side of the overcoat layer away from the second touch layer; wherein the black matrix and the color filter are in direct contact with the overcoat layer.

Optionally, the orthographic projection of the inorganic insulating layer on the base substrate is completely non-overlapping with the orthographic projection of the plurality of bonding pins on the base substrate.

Optionally, the display apparatus further comprises a plurality of touch signal lines at least partially in the peripheral area; wherein a respective touch signal line of the plurality of touch signal lines extends through at least a touch insulating layer, a buffer layer, and the inorganic insulating layer to connect with a respective bonding pin of the plurality of bonding pins; the respective touch signal line is at least partially in a second touch layer.

Optionally, the respective bonding pin comprises a first edge, a second edge, a third edge, and a fourth edge; an orthographic projection of the touch insulating layer on the base substrate substantially covers an orthographic projection of the first edge on the base substrate, substantially covers an orthographic projection of the second edge on the base substrate, substantially covers an orthographic projection of the third edge on the base substrate, and substantially covers an orthographic projection of the fourth edge on the base substrate; the first edge, the second edge, the third edge, and the fourth edge surround a central portion of the respective bonding pin; and the orthographic projection of the touch insulating layer on the base substrate is at least partially non-overlapping with an orthographic projection of the central portion of the respective bonding pin on the base substrate.

Optionally, the respective bonding pin comprises a first edge, a second edge, a third edge, and a fourth edge; an orthographic projection of the touch insulating layer on the base substrate is at least partially non-overlapping with an orthographic projection of the first edge on the base substrate, is at least partially non-overlapping with an orthographic projection of the second edge on the base substrate, is at least partially non-overlapping with an orthographic projection of the third edge on the base substrate, and is at least partially non-overlapping with an orthographic projection of the fourth edge on the base substrate; the first edge, the second edge, the third edge, and the fourth edge surround a central portion of the respective bonding pin; and the orthographic projection of the touch insulating layer on the base substrate is at least partially non-overlapping with an orthographic projection of the central portion of the respective bonding pin on the base substrate.

Optionally, the display apparatus further comprising a first via; wherein the respective touch signal line is connected to the respective bonding pin through the first via; insulating layers between an exposed surface of the respective bonding pin and the first via comprise a sloped portion and a non-sloped portion; a width of the non-sloped portion is greater than a maximum width of the first via along a direction from the exposed surface of the respective bonding pin to the first via.

Optionally, the display apparatus further comprises a second via and a third via; wherein the respective touch signal line comprises a first portion in a first touch layer and a second portion in a second touch layer; the second portion is connected to the first portion through the second via; and the first portion is connected to the respective bonding pin through the third via.

Optionally, the display apparatus further comprises a second via, a third via, and a fourth via, wherein the respective touch signal line comprises a first portion in a first touch layer and a second portion in a second touch layer; the second portion is connected to the first portion through the second via; the first portion is connected to the respective bonding pin through the third via, and through the fourth via, respectively.

Optionally, a fourth distance is greater than a fifth distance; the fourth distance stands for a minimum distance between an orthographic projection of a portion of the first portion in the third via on the base substrate and an orthographic projection of a portion of the first portion in the fourth via on the base substrate; and the fifth distance stands for a minimum distance between an orthographic projection of a portion of the first portion in the third via on the base substrate and an orthographic projection of a position at a portion of the respective bonding pin, where a surface of the portion transitions from being covered by insulating layers to being exposed, on the base substrate.

Optionally, the display apparatus further comprising a first via; wherein the respective touch signal line is connected to the respective bonding pin through the first via; and the first via extends through the touch insulating layer, the buffer layer, and the inorganic insulating layer.

Optionally, the display apparatus further comprises a fifth via; wherein the respective touch signal line is connected to the respective bonding pin through the fifth via; and the fifth via extends through the touch insulating layer, the buffer layer, the inorganic insulating layer, and a first planarization layer.

Optionally, the display apparatus in the peripheral area further comprises a first voltage supply line configured to provide a first voltage supply signal to the display area and a second voltage supply line configured to provide a second voltage supply signal to the display area; wherein an orthographic projection of at least one of the first voltage supply line or the second voltage supply line on the base substrate at least partially overlaps with an orthographic projection of the plurality of bonding pins on the base substrate.

Optionally, in the bonding pin region of the peripheral area, the display apparatus comprises: a first signal line layer on the base substrate; a passivation layer on a side of the first signal line layer away from the base substrate; a second signal line layer on a side of the passivation layer away from the first signal line layer; a first planarization layer on a side of the second signal line layer away from the passivation layer; and the plurality of bonding pins on a side of the first planarization layer away from the second signal line layer.

Optionally, a respective bonding pin of the plurality of bonding pins is in direct contact with the first planarization layer; the first planarization layer in a first region is in direct contact with the respective bonding pin, and is not in contact with the respective bonding pin in a second region adjacent to the first region; a surface of the first planarization layer away from the base substrate includes a first part in direct contact with the respective bonding pin and a second part not in contact with the respective bonding pin, the first part and the second part being on a same side of the first planarization layer, a first relative height is greater than a second relative height with respect to a same horizontal plane; the first relative height is a height of the first part relative to the same horizontal plane; and the second relative height is a height of the second part relative to the same horizontal plane.

Optionally, in the bonding pin region of the peripheral area, the display apparatus comprises: a first signal line layer on the base substrate; a passivation layer on a side of the first signal line layer away from the base substrate; the plurality of bonding pins in a second signal line layer on a side of the passivation layer away from the first signal line layer; and a first planarization layer on a side of the second signal line layer away from the passivation layer.

In another aspect, the present disclosure provides a method of fabricating a display apparatus having a display area and a peripheral area, the peripheral area comprising a bonding pin region; wherein the method comprises: in the display area, forming a pixel driving circuit substrate, forming a plurality of light emitting elements on the pixel driving circuit substrate, and forming an encapsulating layer on a side of the plurality of light emitting elements away from the pixel driving circuit substrate; in the bonding pin region, forming a plurality of bonding pins; forming an inorganic insulating layer on a side of the encapsulating layer in the display area, and on a side of the plurality of bonding pins in the bonding pin region of the peripheral area away from the base substrate; subsequent to forming the inorganic insulating layer, in the display area, forming a black matrix and a color filter on a side of the plurality of light emitting elements away from the pixel driving circuit substrate; and subsequent to forming the black matrix and the color filter, at least partially removing a portion of the inorganic insulating layer in the bonding pin region to expose at least a portion of a respective bonding pin of the plurality of bonding pins.

Optionally, the method further comprises, in the bonding pin region; forming a first signal line layer on the base substrate; forming a passivation layer on a side of the first signal line layer away from the base substrate; forming a second signal line layer on a side of the passivation layer away from the first signal line layer; forming a first planarization layer on a side of the second signal line layer away from the passivation layer; and forming the plurality of bonding pins on a side of the first planarization layer away from the second signal line layer.

In another aspect, the present disclosure further provides a display apparatus, comprising a display area and a peripheral area; wherein, in the display area, the display apparatus comprises a pixel driving circuit substrate, a plurality of light emitting elements on the pixel driving circuit substrate, an encapsulating layer on a side of the plurality of light emitting elements away from the pixel driving circuit substrate, an inorganic insulating layer on a side of the encapsulating layer away from the plurality of light emitting elements; in a bonding pin region of the peripheral area, the display apparatus comprises a base substrate, a plurality of bonding pins on the base substrate; and an orthographic projection of the inorganic insulating layer on the base substrate is at least partially non-overlapping with an orthographic projection of the plurality of bonding pins on the base substrate; wherein the display apparatus further comprises a plurality of touch signal lines at least partially in the peripheral area; and a plurality of first vias; wherein the respective touch signal line is connected to a respective bonding pin of the plurality of bonding pins through a first via of the plurality of first vias; and an exposed surface of the respective bonding pin is spaced apart from the first via.

### BRIEF DESCRIPTION OF THE FIGURES

The following drawings are merely examples for illustrative purposes according to various disclosed embodiments and are not intended to limit the scope of the present invention.

FIG. 1 illustrates a detailed structure in a display area in a display apparatus in some embodiments according to the present disclosure.

FIG. 2 is a schematic diagram illustrating the structure of a display apparatus in some embodiments according to the present disclosure.

FIG. 3 is a schematic diagram illustrating the structure of a display apparatus in some embodiments according to the present disclosure.

FIG. 4 is a schematic diagram illustrating a display area and a peripheral area in a display apparatus in some embodiments according to the present disclosure.

FIG. 5 is a diagram illustrating a portion of a peripheral area in a display apparatus in some embodiments according to the present disclosure.

FIG. 6 is a schematic diagram illustrating the structure of a display apparatus in some embodiments according to the present disclosure.

FIG. 7 shows an undercut erosion occurred at edges of a bonding pin.

FIG. 8A to FIG. 8G illustrates a process of fabricating a display apparatus in some embodiments according to the present disclosure.

FIG. 9 illustrates a connection between a bonding pin and a touch signal line in a display apparatus in some embodiments according to the present disclosure.

FIG. 10 is a plan view of a portion of a display apparatus in a bonding pin region in some embodiments according to the present disclosure.

FIG. 11A illustrates a connection between a bonding pin and a touch signal line in a display apparatus in some embodiments according to the present disclosure.

FIG. 11B illustrates a connection between a bonding pin and a touch signal line in a display apparatus in some embodiments according to the present disclosure.

FIG. 12 illustrates the structure of a respective bonding pin in a display apparatus in some embodiments according to the present disclosure.

FIG. 13 is a plan view of a portion of a display apparatus in a bonding pin region in some embodiments according to the present disclosure.

FIG. 14 illustrates a connection between a bonding pin and a touch signal line in a display apparatus in some embodiments according to the present disclosure.

FIG. 15 is a plan view of a portion of a display apparatus in a bonding pin region in some embodiments according to the present disclosure.

FIG. 16 illustrates a connection between a bonding pin and a touch signal line in a display apparatus in some embodiments according to the present disclosure.

FIG. 17 illustrates a connection between a bonding pin and a touch signal line in a display apparatus in some embodiments according to the present disclosure.

FIG. 18 illustrates a connection between a bonding pin and a touch signal line in a display apparatus in some embodiments according to the present disclosure.

FIG. 19 illustrates a connection between a bonding pin and a touch signal line in a display apparatus in some embodiments according to the present disclosure.

FIG. 20A to FIG. 20F illustrates a process of fabricating a display apparatus in some embodiments according to the present disclosure.

FIG. 21 illustrates a connection between a bonding pin and a touch signal line in a display apparatus in some embodiments according to the present disclosure.

FIG. 22 illustrates a connection between a bonding pin and a touch signal line in a display apparatus in some embodiments according to the present disclosure.

FIG. 23 illustrates the structure of a respective bonding pin in a display apparatus in some embodiments according to the present disclosure.

FIG. 24 is a plan view of a portion of a display apparatus in a bonding pin region in some embodiments according to the present disclosure.

FIG. 25 illustrates a connection between a bonding pin and a touch signal line in a display apparatus in some embodiments according to the present disclosure.

FIG. 26 is a plan view of a portion of a display apparatus in a bonding pin region in some embodiments according to the present disclosure.

FIG. 27 illustrates a connection between a bonding pin and a touch signal line in a display apparatus in some embodiments according to the present disclosure.

FIG. 28 illustrates a connection between a bonding pin and a touch signal line in a display apparatus in some embodiments according to the present disclosure.

FIG. 29 illustrates a connection between a bonding pin and a touch signal line in a display apparatus in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, a display apparatus and a method of fabricating a display apparatus that substantially obviate one or more of the problems due to limitations and disadvantages of the related art. In one aspect, the present disclosure provides a display apparatus. In some embodiments, the display apparatus includes a display area and a peripheral area. Optionally, in the display area, the display apparatus comprises a pixel driving circuit substrate, a plurality of light emitting elements on the pixel driving circuit substrate, an encapsulating layer on a side of the plurality of light emitting elements away from the pixel driving circuit substrate, an inorganic insulating layer on a side of the encapsulating layer away from the plurality of light emitting elements. Optionally, in a bonding pin region of the peripheral area, the display apparatus comprises a base substrate, a plurality of bonding pins on the base substrate. Optionally, an orthographic projection of the inorganic insulating layer on the base substrate is at least partially non-overlapping with an orthographic projection of the plurality of bonding pins on the base substrate.

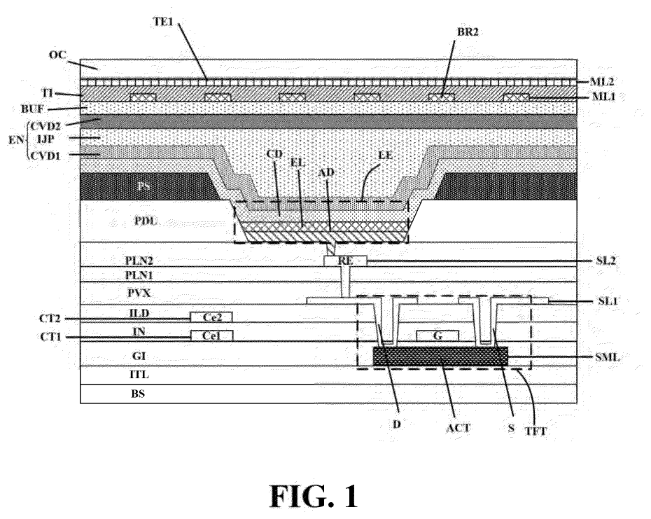

FIG. 1 illustrates a detailed structure in a display area in a display apparatus in some embodiments according to the present disclosure. Referring to FIG. 1, the display apparatus in the display area in some embodiments includes a base substrate BS (e.g., a flexible base substrate); an inter-layer ITL on the base substrate BS; an active layer ACT of a respective one of a plurality of thin film transistors TFT on a side of the inter-layer ITL away from the base substrate BS; a gate insulating layer GI on a side of the active layer ACT away from the base substrate BS; a gate electrode G and a first capacitor electrode Ce1 (both are parts of a first conductive layer) on a side of the gate insulating layer GI away from the base substrate BS; an insulating layer IN on a side of the gate electrode G and the first capacitor electrode Ce1 away from the gate insulating layer GI; a second capacitor electrode Ce2 (a part of a second conductive layer) on a side of the insulating layer IN away from the gate insulating layer G; an inter-layer dielectric layer ILD on a side of the second capacitor electrode Ce2 away from the gate insulating layer GI; a source electrode S and a drain electrode D (parts of a first signal line layer) on a side of the inter-layer dielectric layer ILD away from the gate insulating layer GI; a passivation layer PVX on a side of the source electrode S and the drain electrode D away from the inter-layer dielectric layer ILD; a first planarization layer PLN1 on a side of the passivation layer PVX away from the inter-layer dielectric layer ILD; a relay electrode RE (part of a second signal line layer) on side of the first planarization layer PLN1 away from the passivation layer PVX; a second planarization layer PLN2 on a side of relay electrode RE away from the first planarization layer PLN1; a pixel definition layer PDL defining a subpixel aperture and on a side of the second planarization layer PLN2 away from the base substrate BS; and a light emitting element LE in the subpixel aperture. The light emitting element LE includes an anode AD on a side of the second planarization layer PLN2 away from the first planarization layer PLN1; a light emitting layer EL on a side of the anode AD away from the second planarization layer PLN2; and a cathode layer CD on a side of the light emitting layer EL away from the anode AD. The display apparatus in the display area further includes an encapsulating layer EN encapsulating the light emitting element LE, and on a side of the cathode layer CD away from the base substrate BS. The encapsulating layer EN in some embodiments includes a first inorganic encapsulating sub-layer CVD1 on a side of the cathode layer CD away from the base substrate BS, an organic encapsulating sub-layer IP on a side of the first inorganic encapsulating sub-layer CVD1 away from the base substrate BS, and a second inorganic encapsulating sub-layer CVD2 on a side of the organic encapsulating sub-layer UP away from the first inorganic encapsulating sub-layer CVD1. The display apparatus in the display area further includes a buffer layer BUF on a side of the encapsulating layer EN away from the base substrate BS; a plurality of second electrode bridges BR2 on a side of the buffer layer BUF away from the encapsulating layer EN; a touch insulating layer TI on a side of the plurality of second electrode bridges BR2 away from the buffer layer BUF; a plurality of first touch electrodes TE1 on a side of the touch insulating layer TI away from the buffer layer BUF; and an overcoat layer OC on a side of the plurality of first touch electrodes TE1 away from the touch insulating layer TI. Optionally, the display apparatus in the display area does not include the passivation layer PVX, e.g., the inter-layer dielectric layer ILD is in direct contact with the first planarization layer PLN1.

Referring to FIG. 1, the display apparatus includes a semiconductor material layer SML, a first conductive layer CT1, a second conductive layer CT2, a first signal line layer SL1, and a second signal line layer SL2. The display apparatus further includes an insulating layer IN between the first conductive layer CT1 and the second conductive layer CT2; an inter-layer dielectric layer ILD between the second conductive layer CT2 and the first signal line layer SL1; and at least a passivation layer PVX or a first planarization layer PLN1 between the first signal line layer SL1 and the second signal line layer SL2.

Referring to FIG. 1, the plurality of second electrode bridges BR2 are in a first touch layer ML1, and the plurality of first touch electrodes TE1 are in a second touch layer ML2.

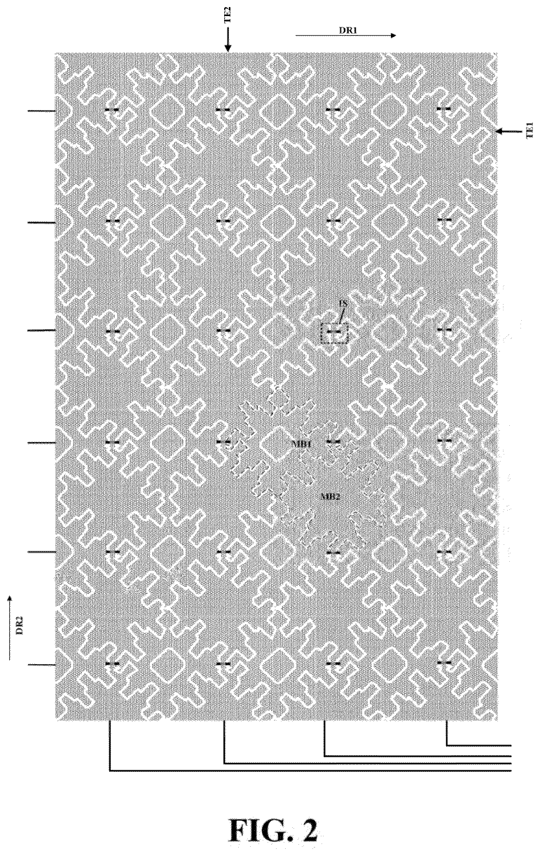

FIG. 2 is a schematic diagram illustrating the structure of a display panel in some embodiments according to the present disclosure. Referring to FIG. 2, the touch control structure in some embodiments includes a plurality of first mesh electrodes TE1 arranged in a plurality of rows and a plurality of second mesh electrodes TE2 arranged in a plurality of columns. The plurality of first mesh electrodes TE1 are arranged in a plurality of rows, each of the plurality of rows is a respective one of the plurality of first mesh electrodes TE1. The plurality of second mesh electrodes TE2 arranged in a plurality of columns, each of the plurality of columns is a respective one of the plurality of second mesh electrodes TE2. Optionally, the touch control structure is a mutual capacitance type touch control structure. Optionally, the plurality of first mesh electrodes TE1 are a plurality of touch sensing electrodes, and the plurality of second mesh electrodes TE2 are a plurality of touch scanning electrodes. Optionally, the plurality of first mesh electrodes TE1 are a plurality of touch scanning electrodes, and the plurality of second mesh electrodes TE2 are a plurality of touch sensing electrodes.

As shown in FIG. 2, a respective one of the plurality of first mesh electrodes TE1 includes a plurality of first mesh blocks MB1 consecutively electrically connected in a respective row along a first direction DR1, a respective one of the plurality of second mesh electrodes TE2 includes a plurality of second mesh blocks MB2 consecutively electrically connected in a respective column along a second direction DR2. In FIG. 2, a respective one of the plurality of first mesh blocks MB1 and a respective one of the plurality of second mesh blocks MB2 are depicted as blocks respectively encircled by dotted lines.

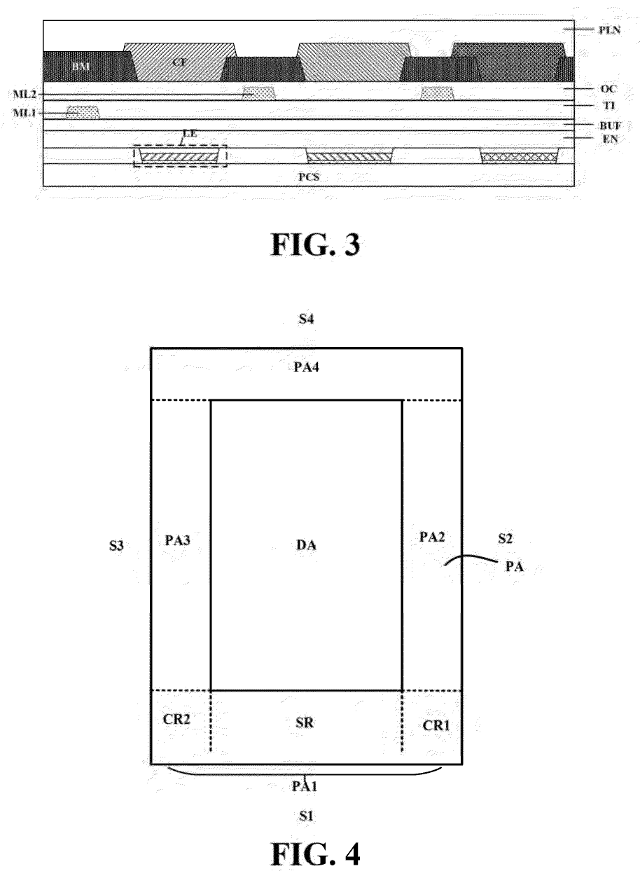

FIG. 3 is a schematic diagram illustrating the structure of a display apparatus in some embodiments according to the present disclosure. Referring to FIG. 3, the display apparatus includes a pixel driving circuit substrate PCS comprising a plurality of pixel driving circuit for driving light emission of the display apparatus, a plurality of light emitting elements LE connected to the plurality of pixel driving circuits, an encapsulating layer EN on a side of the plurality of light emitting elements LE away from the pixel driving circuit substrate PCS, a buffer layer BUF on a side of the encapsulating layer EN away from the plurality of light emitting elements LE, a first touch layer ML1 on a side of the buffer layer BUF away from the encapsulating layer EN, a touch insulating layer TI on a side of the first touch layer ML1 away from the buffer layer BUF, a second touch layer ML2 on a side of the touch insulating layer TI away from the first touch layer ML1, an overcoat layer OC on a side of the second touch layer MU away from the touch insulating layer TI, a black matric BM and a color filter CF on a side of the overcoat layer OC away from the second touch layer ML2, and a planarization layer PLN on a side of the black matric BM and the color filter CF away from the overcoat layer OC.

FIG. 4 is a schematic diagram illustrating a display area and a peripheral area in a display apparatus in some embodiments according to the present disclosure. Referring to FIG. 4, in some embodiments, the peripheral area PA includes a first sub-area PA1 on a first side S1 of the display area DA, a second sub-area PA2 on a second side S2 of the display area DA, a third sub-area PA3 on a third side S3 of the display area DA, a fourth sub-area PA4 on a fourth side S4 of the display area DA. Optionally, the first side S1 and the fourth side S4 are opposite to each other. Optionally, the second side S2 and the third side S3 are opposite to each other. Optionally, the first sub-area PA1 is a sub-area where the plurality of signal lines are connected to an integrated circuit (e.g., an integrated touch control circuit).

In some embodiments, the first sub-area PA1 includes a side region SR and one or more corner regions (e.g., a first corner region CR1 and a second corner region CR2). The one or more corner regions are respectively at a corner of the array substrate. The one or more corner regions respectively connect the side region SR to one or more adjacent sub-areas of the peripheral area PA. For example, the first corner region CR1 connects the side region SR to the second sub-area PA2, and the second corner region CR2 connects the side region SR to the third sub-area PA3.

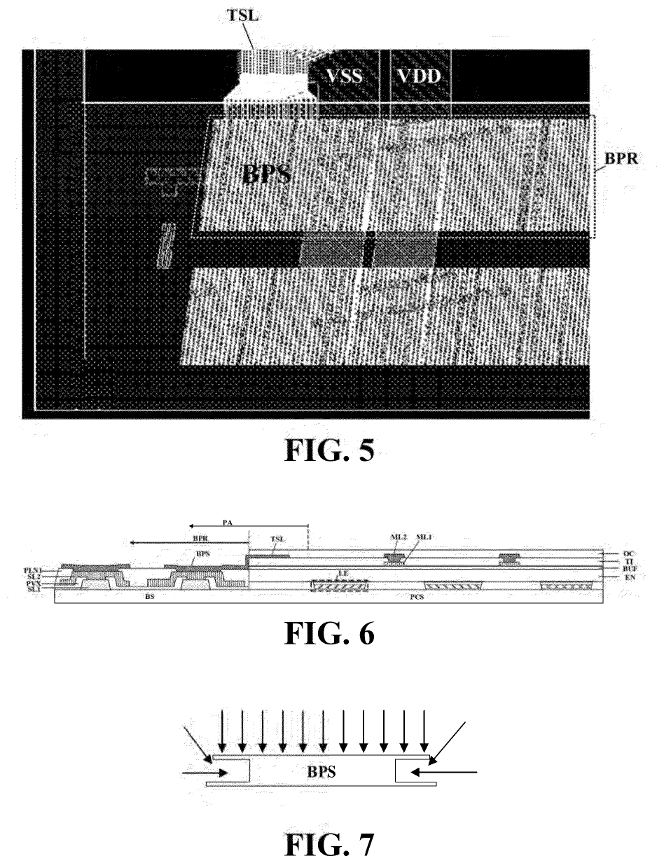

FIG. 5 is a diagram illustrating a portion of a peripheral area in a display apparatus in some embodiments according to the present disclosure. Referring to FIG. 5, the display apparatus in the peripheral area includes a plurality of bonding pins BPS configured to bond with a touch integrated circuit or a flexible printed circuit. The plurality of bonding pins BPS are in a bonding pin region BPR. The display apparatus in the peripheral area further includes various signal lines such as a first voltage supply line VDD configured to provide a first voltage supply signal to the display area and a second voltage supply line VSS configured to provide a second voltage supply signal to the display area. In some embodiments, the first voltage supply line VDD extends at least partially in the bonding pin region BPR, e.g., extending through the bonding pin region BPR. In some embodiments, the second voltage supply line VSS extends at least partially in the bonding pin region BPR, e.g., extending through the bonding pin region BPR. In some embodiments, an orthographic projection of the first voltage supply line VDD on a base substrate at least partially overlaps with an orthographic projection of the plurality of bonding pins BPS on the base substrate. In some embodiments, an orthographic projection of the second voltage supply line VSS on a base substrate at least partially overlaps with an orthographic projection of the plurality of bonding pins BPS on the base substrate. In one example, FIG. 5 shows a first sub-area PA1 of the peripheral area denoted in FIG. 4.

FIG. 6 is a schematic diagram illustrating the structure of a display apparatus in some embodiments according to the present disclosure. Referring to FIG. 6, the display apparatus in some embodiments includes a plurality of touch signal lines TSL in the peripheral area PA. The plurality of touch signal lines TSL is connected to touch electrodes in the display area (e.g., touch electrodes in the first touch layer ML1 or the second touch layer ML2), and is connected to a plurality of bonding pins.

Referring to FIG. 6, the peripheral area PA of the display apparatus includes a bonding pin region BPR having a plurality of bonding pins BPS. The plurality of bonding pins BPS are connected to the plurality of touch signal lines TSL in the peripheral area PA. The plurality of bonding pins BPS are configured to bond with a touch integrated circuit or a flexible printed circuit. In some embodiments, the peripheral area PA of the display apparatus further includes at least one of a first signal line layer SL1 on a base substrate BS and a second signal line layer SL2 on a side of the first signal line layer SL1 away from the base substrate BS. The second signal line layer SL2 is on a side of the plurality of bonding pins BPS closer to the base substrate BS. In some embodiments, an electrode in the second signal line layer SL2 and/or an electrode in the first signal line layer SL1 are connected to one or more bonding pins of the plurality of bonding pins BPS, and function as relay electrodes connecting the one or more bonding pins to signal lines.

Referring to FIG. 3 and FIG. 6, in some embodiments, the display apparatus is a flexible display apparatus. To achieve an enhanced flexibility in the display apparatus, certain insulating layers in the display apparatus are made of a polymeric organic material. For example, referring to FIG. 3 and FIG. 6, the touch insulating layer TI and the overcoat layer OC in some embodiments are made of a polymeric flexible organic material. When the touch insulating layer TI and the overcoat layer OC are made of a polymeric flexible organic material, they are absent in the bonding pin region BPR.

Referring to FIG. 3, in some embodiments, the display apparatus is a color filter on encapsulation display apparatus, in which the color filter CF and the black matrix BM are formed directly on the overcoat layer OC in the display area of the display apparatus. Because the touch insulating layer TI and the overcoat layer OC are absent in the bonding pin region BPR, the plurality of bonding pins BPS are at least partially exposed to alkaline developing solutions used in the process of forming at least one of the color filter CF and the black matrix BM. In particular, edges of the plurality of bonding pins BPS are prone to undercut erosion caused by the alkaline developing solutions. FIG. 7 shows an undercut erosion occurred at edges of a bonding pin. The undercut erosion results in a decreased effective width of the bonding pin, and defective black dot issues occur when the bonding pin is bonded to the integrated circuit or the flexible printed circuit.

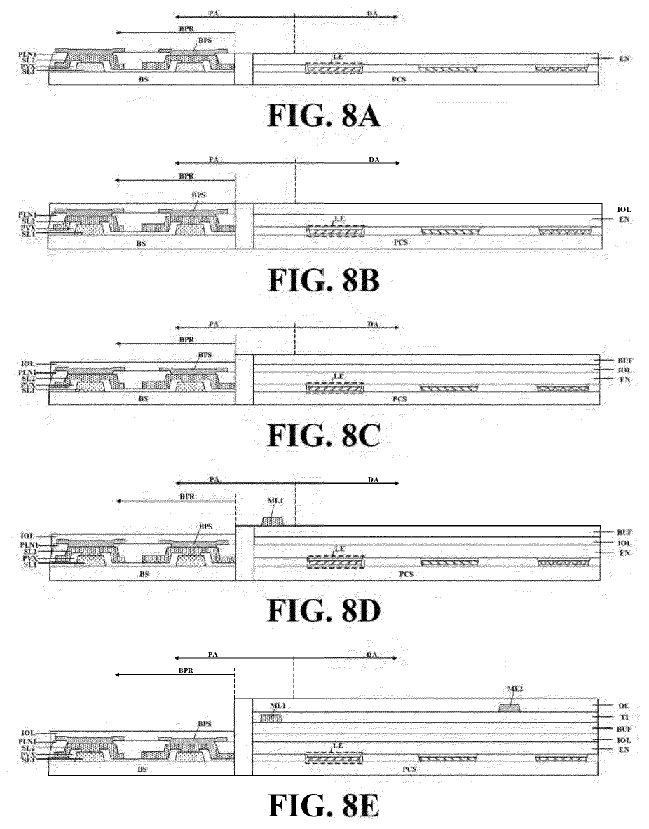

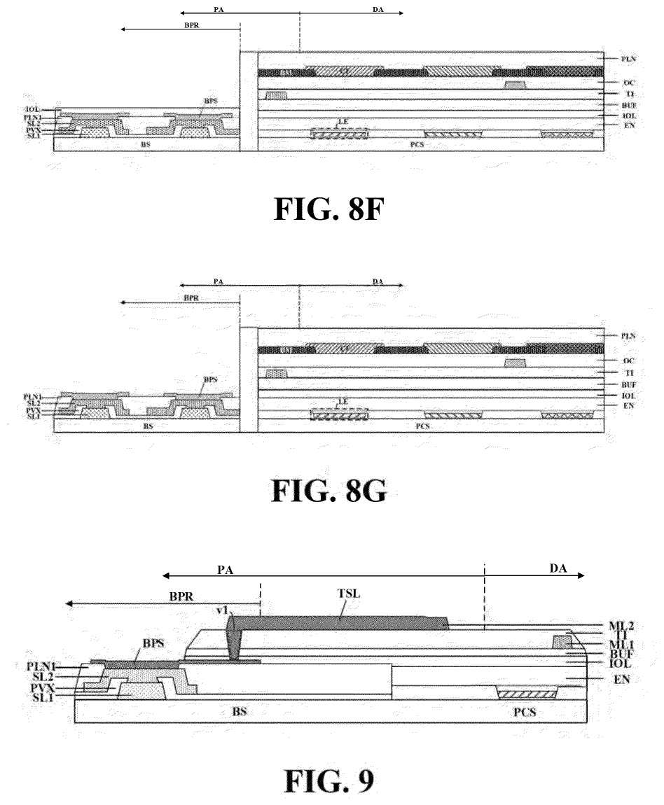

The inventors of the present disclosure discover that the display apparatus according to the present disclosure obviates the issues discussed above. FIG. 8A to FIG. 8G illustrates a process of fabricating a display apparatus in some embodiments according to the present disclosure. Referring to FIG. 8A, a plurality of light emitting elements LE are formed in a display area DA of the display apparatus, and an encapsulating layer EN is formed on a side of the plurality of light emitting elements LE away from the pixel driving circuit substrate PCS. In a bonding pin region BPR of the peripheral area PA, a first signal line layer SL1 is formed on a base substrate BS, a passivation layer PVX is formed on a side of the first signal line layer SL1 away from the base substrate BS, a second signal line layer SL2 is formed on a side of the passivation layer PVX away from the base substrate BS, a first planarization layer PLN1 is formed on a side of the second signal line layer SL2 away from the base substrate BS, and a plurality of bonding pins BPS are formed on a side of the first planarization layer PLN1 away from the base substrate BS. In this step, the plurality of bonding pins BPS are unprotected, and a surface of the plurality of bonding pins BPS is exposed.

In one example, the plurality of bonding pins BPS are in a same layer as a conductive component on the encapsulating layer EN or the second planarization layer PLN2. As used herein, the term “same layer” refers to the relationship between the layers simultaneously formed in the same step. In one example, the plurality of bonding pins BPS and the conductive component on the encapsulating layer EN are in a same layer when they are formed as a result of one or more steps of a same patterning process performed in a material deposited in a same deposition process. In another example, the plurality of bonding pins BPS and the conductive component on the encapsulating layer EN can be formed in a same layer by simultaneously performing the step of forming the plurality of bonding pins BPS and the step of forming the conductive component on the encapsulating layer EN. The term “same layer” does not always mean that the thickness of the layer or the height of the layer in a cross-sectional view is the same.

In another example, the plurality of bonding pins BPS are in a same layer as an anode of a light emitting element.

Referring to FIG. 8B, an inorganic insulating layer IOL is formed on a side of the encapsulating layer EN in the display area DA, and on a side of the plurality of bonding pins BPS in the bonding pin region BPR of the peripheral area PA away from a base substrate BS. Subsequent to forming the inorganic insulating layer IOL, the plurality of bonding pins BPS are protected by the inorganic insulating layer IOL from erosion in subsequent fabrication processes.

In some embodiments, a first relative height between a respective bonding pin of the plurality of bonding pins BPS to a surface of the base substrate BS in the bonding pin region of the peripheral area PA is less than a second relative height between the inorganic insulating layer IOL and a surface of a same base substrate extending from the peripheral area PA to the display area DA. The inventors of the present disclosure discover that, by having the first relative height less than the second relative height, damages to the plurality of bonding pins BPS by masks during the fabricating process can be avoided.

Referring to FIG. 8C, a buffer layer BUF is formed on a side of the inorganic insulating layer IOL away from the encapsulating layer EN in the display area DA.

Referring to FIG. 8D, a first touch layer ML is formed on a side of the buffer layer BUF away from inorganic insulating layer IOL in the display area DA.

Referring to FIG. 8E, in the display area DA, a touch insulating layer TI is formed on a side of the first touch layer ML1 away from the buffer layer BUF, a second touch layer ML2 is formed on a side of the touch insulating layer TI away from the buffer layer BUF, and an overcoat layer OC is formed on a side of the second touch layer ML2 away from touch insulating layer TI. Optionally, the buffer layer BUF, the touch insulating layer TI, and the overcoat layer OC are made of a polymeric organic material.

Referring to FIG. 8F, in the display area DA, a black matrix BM and a color filter CF are formed on a side of the overcoat layer OC away from the touch insulating layer TI, and a planarization layer PLN is formed on a side of the black matrix BM and the color filter CF away from the overcoat layer OC. During this process, as discussed above, alkaline developing solutions are used in patterning the black matrix BM and/or the color filter CF. The plurality of bonding pins BPS in the bonding pin region BPR of the peripheral area PA are covered by the inorganic insulating layer IOL, and are protected from the alkaline developing solutions. The undercut erosion to the plurality of bonding pins BPS can be avoided.

Referring to FIG. 8G, subsequent to forming the black matrix BM and the color filter CF, the inorganic insulating layer IOL in the bonding pin region BPR of the peripheral area PA is at least partially removed, exposing at least a portion of a respective bonding pin of the plurality of bonding pins BPS.

In some embodiments, the display apparatus includes a display area and a peripheral area. In some embodiments, in the display area, the display apparatus includes a pixel driving circuit substrate PCS, a plurality of light emitting elements LE on the pixel driving circuit substrate PCS, an encapsulating layer EN on a side of the plurality of light emitting elements LE away from the pixel driving circuit substrate PCS, an inorganic insulating layer 101 on a side of the encapsulating layer EN away from the plurality of light emitting elements LE, a buffer layer BUF on a side of the inorganic insulating layer IOL away from the encapsulating layer EN, a first touch layer ML1 on a side of the buffer layer BUF away from the inorganic insulating layer IOL, a touch insulating layer TI on a side of the first touch layer ML1 away from the buffer layer BUF, a second touch layer ML2 on a side of the touch insulating layer TI away from the first touch layer ML1, an overcoat layer OC on a side of the second touch layer ML2 away from the touch insulating layer TI, and a black matrix BM and a color filter CF on a side of the overcoat layer OC away from the second touch layer ML2.

In some embodiments, thicknesses of at least two of the touch insulating layer TI, the inorganic insulating layer IOL, and the buffer layer BUF are different from each other. Optionally, a thickness of the touch insulating layer TI is greater than a thickness of the inorganic insulating layer IOL, and is greater than a thickness of the buffer layer BUF. Optionally, the thickness of the buffer layer BUF is greater than the thickness of the inorganic insulating layer IOL.

In some embodiments, in the display area, the display apparatus further includes a planarization layer PLN on a side of the black matrix BM and the color filter CF away from the overcoat layer OC.

In some embodiments, the buffer layer BUF, the touch insulating layer TI, and the overcoat layer OC are made of a polymeric organic material.

In some embodiments, in a bonding pin region BPR of the peripheral area PA, the display apparatus includes a base substrate BS, a first signal line layer SL1 on the base substrate BS, a passivation layer PVX on a side of the first signal line layer SL1 away from the base substrate BS, a second signal line layer SL2 on a side of the passivation layer PVX away from the first signal line layer SL1, a first planarization layer PLN1 on a side of the second signal line layer SL2 away from the passivation layer PVX, and a plurality of bonding pins BPS on a side of the first planarization layer PLN1 away from the second signal line layer SL2.

In some embodiments, the inorganic insulating layer is at least partially absent in the bonding pin region BPR. Optionally, the inorganic insulating layer IOL is completely absent in the bonding pin region BPR. Optionally, an orthographic projection of the inorganic insulating layer IOL on a base substrate is at least partially non-overlapping with (e.g., at least 50% non-overlapping with, at least 60% non-overlapping with, at least 70% non-overlapping with, at least 80% non-overlapping with, at least 90% non-overlapping with, at least 95% non-overlapping with, at least 99% non-overlapping with) an orthographic projection of the plurality of bonding pins BPS on the base substrate. Optionally, the orthographic projection of the inorganic insulating layer IOL on the base substrate is completely non-overlapping with the orthographic projection of the plurality of bonding pins BPS on the base substrate. By having this intricate structure, the plurality of bonding pins BPS remains substantially intact during the fabricating process of the black matrix BM and the color filter CF, avoiding the undercut issue.

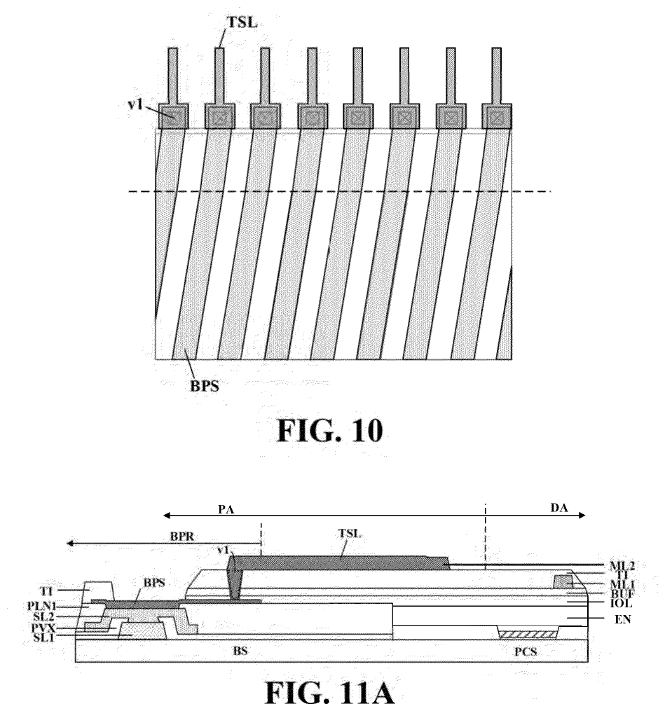

FIG. 9 illustrates a connection between a bonding pin and a touch signal line in a display apparatus in some embodiments according to the present disclosure. FIG. 10 is a plan view of a portion of a display apparatus in a bonding pin region in some embodiments according to the present disclosure. Referring to FIG. 9 and FIG. 10, in some embodiments, the display apparatus in the bonding pin region BPR of the peripheral area PA includes a base substrate BS, a first signal line layer SL1 on the base substrate BS, a passivation layer PVX on a side of the first signal line layer SL1 away from the base substrate BS, a second signal line layer SL2 on a side of the passivation layer PVX away from the first signal line layer SL1, a first planarization layer PLN1 on a side of the second signal line layer SL2 away from the passivation layer PVX, and a plurality of bonding pins BPS on a side of the first planarization layer PLN1 away from the second signal line layer SL2.

In some embodiments, the display apparatus includes a plurality of touch signal lines TSL at least partially in the peripheral area PA. In some embodiments, in the peripheral area PA and outside the bonding pin region BPR, the display apparatus includes a base substrate BS, a passivation layer PVX on the base substrate BS, a first planarization layer PLN1 on a side of the passivation layer PVX away from the base substrate BS, an inorganic insulating layer IOL on a side of the first planarization layer PLN1 away from the passivation layer PVX, a buffer layer BUF on a side of the inorganic insulating layer IOL away from the first planarization layer PLN1, a touch insulating layer TI on a side of the buffer layer BUF away from the inorganic insulating layer IOL, and a plurality of touch signal line TSL on a side of the touch insulating layer TI away from the buffer layer BUF.

In some embodiments, in the display area DA, the display apparatus includes a pixel driving circuit substrate PCS, a plurality of light emitting elements LE on the pixel driving circuit substrate PCS, an encapsulating layer EN on a side of the plurality of light emitting elements LE away from the pixel driving circuit substrate PCS, an inorganic insulating layer IOL on a side of the encapsulating layer EN away from the plurality of light emitting elements LE, a buffer layer BUF on a side of the inorganic insulating layer IOL away from the encapsulating layer EN, a first touch layer ML1 on a side of the buffer layer BUF away from the inorganic insulating layer IOL, a touch insulating layer TI on a side of the first touch layer MLA away from the buffer layer BUF, and a second touch layer ML2 on a side of the touch insulating layer TI away from the first touch layer ML1.

In some embodiments, the plurality of touch signal lines TSL are in the second touch layer ML.

In some embodiments, an orthographic projection of the inorganic insulating layer IOL on the base substrate BS at least partially overlaps with an orthographic projection of the plurality of bonding pins BPS on the base substrate BS. In some embodiments, a respective touch signal line of the plurality of touch signal lines TSL extends through the touch insulating layer TI, the buffer layer BUF, and the inorganic insulating layer IOL to connect with a respective bonding pin of the plurality of bonding pins BPS. Optionally, the display apparatus includes a first via v1. The respective touch signal line of the plurality of touch signal lines TSL is connected to the respective bonding pin of the plurality of bonding pins BPS through the first via v1. In one example, the first via v1 extends through the touch insulating layer TI, the buffer layer BUF, and the inorganic insulating layer IOL.

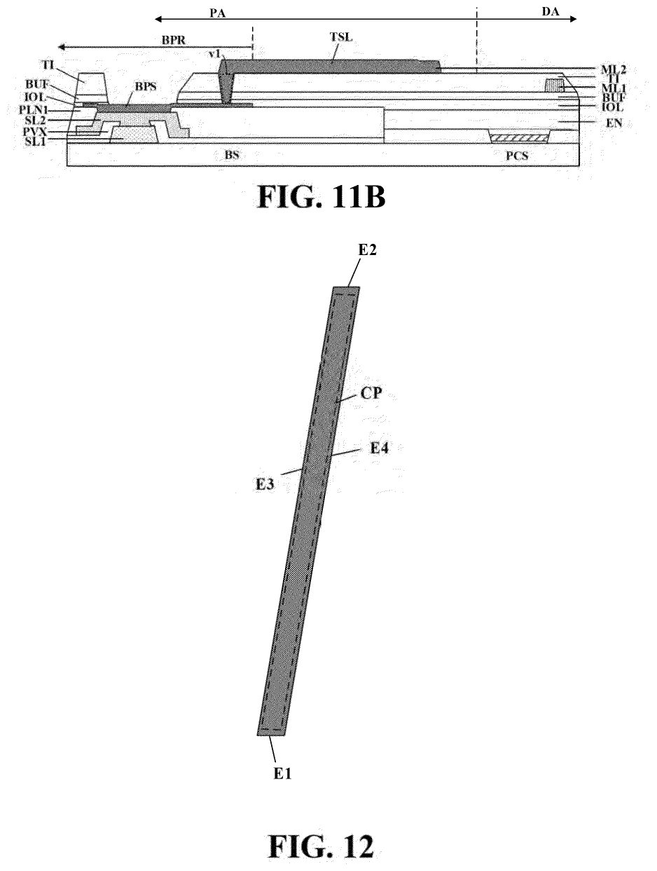

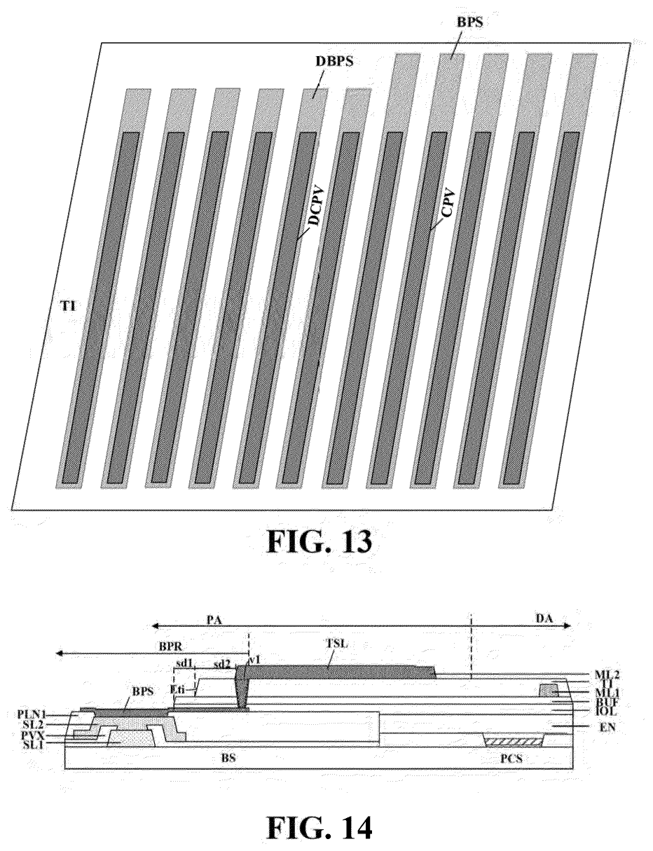

FIG. 11A illustrates a connection between a bonding pin and a touch signal line in a display apparatus in some embodiments according to the present disclosure. FIG. 12 illustrates the structure of a respective bonding pin in a display apparatus in some embodiments according to the present disclosure. FIG. 13 is a plan view of a portion of a display apparatus in a bonding pin region in some embodiments according to the present disclosure. Referring to FIG. 11A, FIG. 12, and FIG. 13, in some embodiments, the display apparatus in the bonding pin region BPR of the peripheral area PA includes a base substrate BS, a first signal line layer SL1 on the base substrate BS, a passivation layer PVX on a side of the first signal line layer SL1 away from the base substrate BS, a second signal line layer SL2 on a side of the passivation layer PVX away from the first signal line layer SL1, a first planarization layer PLN1 on a side of the second signal line layer SL2 away from the passivation layer PVX, a plurality of bonding pins BPS on a side of the first planarization layer PLN1 away from the second signal line layer SL2, and a touch insulating layer TI on a side of the plurality of bonding pins BPS away from the first planarization layer PLN1.

In some embodiments, the display apparatus includes a plurality of touch signal lines TSL at least partially in the peripheral area PA. In some embodiments, in the peripheral area PA and outside the bonding pin region BPR, the display apparatus includes a base substrate BS, a passivation layer PVX on the base substrate BS, a first planarization layer PLN1 on a side of the passivation layer PVX away from the base substrate BS, an inorganic insulating layer IOL on a side of the first planarization layer PLN1 away from the passivation layer PVX, a buffer layer BUF on a side of the inorganic insulating layer IOL away from the first planarization layer PLN1, a touch insulating layer TI on a side of the buffer layer BUF away from the inorganic insulating layer IOL, and a plurality of touch signal line TSL on a side of the touch insulating layer TI away from the buffer layer BUF.

In some embodiments, in the display area DA, the display apparatus includes a pixel driving circuit substrate PCS, a plurality of light emitting elements LE on the pixel driving circuit substrate PCS, an encapsulating layer EN on a side of the plurality of light emitting elements LE away from the pixel driving circuit substrate PCS, an inorganic insulating layer IOL on a side of the encapsulating layer EN away from the plurality of light emitting elements LE, a buffer layer BUF on a side of the inorganic insulating layer IOL away from the encapsulating layer EN, a first touch layer ML1 on a side of the buffer layer BUF away from the inorganic insulating layer IOL, a touch insulating layer TI on a side of the first touch layer ML1 away from the buffer layer BUF, and a second touch layer ML2 on a side of the touch insulating layer TI away from the first touch layer ML1. In some embodiments, the plurality of touch signal lines TSL are in the second touch layer ML2.

In some embodiments, an orthographic projection of the inorganic insulating layer IOL on the base substrate BS at least partially overlaps with an orthographic projection of the plurality of bonding pins BPS on the base substrate BS. In some embodiments, a respective touch signal line of the plurality of touch signal lines TSL extends through the touch insulating layer TI, the buffer layer BUF, and the inorganic insulating layer IOL to connect with a respective bonding pin of the plurality of bonding pins BPS. Optionally, the display apparatus includes a first via v1. The respective touch signal line of the plurality of touch signal lines TSL is connected to the respective bonding pin of the plurality of bonding pins BPS through the first via v1. In one example, the first via v1 extends through the touch insulating layer TI, the buffer layer BUF, and the inorganic insulating layer IOL.

In some embodiments, a respective bonding pin of the plurality of bonding pins BPS includes a first edge E1, a second edge E2, a third edge E3, and a fourth edge E4. Optionally, the first edge E1 and the second edge F2 are opposite to each other. Optionally, the third edge E3 and the fourth edge E4 are opposite to each other. The first edge E1 and the second edge E2 are connected through the third edge E3, and are connected through the fourth edge E4. The third edge E3 and the fourth edge E4 are connected through the first edge E1, and are connected through the second edge E2. The first edge E1, the second edge E2, the third edge E3, and the fourth edge E4 surround a central portion CP of the respective bonding pin.

In some embodiments, an orthographic projection of the touch insulating layer TI on a base substrate BS substantially covers (e.g., at least 80% covers, at least 85% covers, at least 90% covers, at least 95% covers, at least 99% covers, or completely covers) an orthographic projection of the first edge E1 on the base substrate BS, substantially covers (e.g., at least 80% covers, at least 85% covers, at least 90% covers, at least 95% covers, at least 99% covers, or completely covers) an orthographic projection of the second edge E2 on the base substrate BS, substantially covers (e.g., at least 80% covers, at least 85% covers, at least 90% covers, at least 95% covers, at least 99% covers, or completely covers) an orthographic projection of the third edge E3 on the base substrate BS, and substantially covers (e.g., at least 80% covers, at least 85% covers, at least 90% covers, at least 95% covers, at least 99% covers, or completely covers) an orthographic projection of the fourth edge E4 on the base substrate BS.

In some embodiments, the orthographic projection of the touch insulating layer TI on the base substrate BS is at least partially (e.g., at least 10%, at least 20%, at least 30%, at least 40%, at least 50%, at least 60%, at least 70%, at least 80%, at least 90%, or at least 95%) non-overlapping with an orthographic projection of the central portion CP of the respective bonding pin on the base substrate BS.

Referring to FIG. 11A, in a sub-region of the bonding pin region BPR on a side of the plurality of bonding pins BPS away from the display area DA, the inorganic insulating layer IOL and the buffer layer BUF are absent, only a portion of the touch insulating layer TI is present.

FIG. 11B illustrates a connection between a bonding pin and a touch signal line in a display apparatus in some embodiments according to the present disclosure. Referring to FIG. 11B, FIG. 12, and FIG. 13, in some embodiments, the touch insulating layer TI, the inorganic insulating layer IOL, and the buffer layer BUF are present in a sub-region of the bonding pin region BPR on a side of the plurality of bonding pins BPS away from the display area DA.

In some embodiments, an orthographic projection of the inorganic insulating layer IOL on a base substrate BS substantially covers (e.g., at least 80% covers, at least 85% covers, at least 90% covers, at least 95% covers, at least 99% covers, or completely covers) an orthographic projection of the first edge E1 on the base substrate BS, substantially covers (e.g., at least 80% covers, at least 85% covers, at least 90% covers, at least 95% covers, at least 99% covers, or completely covers) an orthographic projection of the second edge E2 on the base substrate BS, substantially covers (e.g., at least 80% covers, at least 85% covers, at least 90% covers, at least 95% covers, at least 99% covers, or completely covers) an orthographic projection of the third edge E3 on the base substrate BS, and substantially covers (e.g., at least 80% covers, at least 85% covers, at least 90% covers, at least 95% covers, at least 99% covers, or completely covers) an orthographic projection of the fourth edge E4 on the base substrate BS.

In some embodiments, the orthographic projection of the inorganic insulating layer IOL on the base substrate BS is at least partially (e.g., at least 10%, at least 20%, at least 30%, at least 40%, at least 50%, at least 60%, at least 70%, at least 80%, at least 90%, or at least 95%) non-overlapping with an orthographic projection of the central portion CP of the respective bonding pin on the base substrate BS.

In some embodiments, an orthographic projection of the buffer layer BUF on a base substrate BS substantially covers (e.g., at least 80% covers, at least 85% covers, at least 90% covers, at least 95% covers, at least 99% covers, or completely covers) an orthographic projection of the first edge E1 on the base substrate BS, substantially covers (e.g., at least 80% covers, at least 85% covers, at least 90% covers, at least 95% covers, at least 99% covers, or completely covers) an orthographic projection of the second edge E2 on the base substrate BS, substantially covers (e.g., at least 80% covers, at least 85% covers, at least 90% covers, at least 95% covers, at least 99% covers, or completely covers) an orthographic projection of the third edge E3 on the base substrate BS, and substantially covers (e.g., at least 80% covers, at least 85% covers, at least 90% covers, at least 95% covers, at least 99% covers, or completely covers) an orthographic projection of the fourth edge E4 on the base substrate BS.

In some embodiments, the orthographic projection of the buffer layer BUF on the base substrate BS is at least partially (e.g., at least 10%, at least 20%, at least 30%, at least 40%, at least 50%, at least 60%, at least 70%, at least 80%, at least 90%, or at least 95%) non-overlapping with an orthographic projection of the central portion CP of the respective bonding pin on the base substrate BS.

In some embodiments, referring to FIG. 11A, FIG. 11B, FIG. 12, and FIG. 13, the array substrate includes a plurality of central portion vias CPV. A respective central portion via of the plurality of central portion vias CPV extends through at least the touch insulating layer TI, exposing at least a portion of a central portion CP of a plurality of central portions. In some embodiments, extension directions of the plurality of central portions are substantially parallel to each other. In some embodiments, extension directions of the plurality of central portion vias CPV are substantially parallel to each other. As used herein, the term “substantially parallel” means that an angle is in the range of 0 degree to approximately 45 degrees, e.g., 0 degree to approximately 5 degrees, 0 degree to approximately 10 degrees, 0 degree to approximately 15 degrees, 0 degree to approximately 20 degrees, 0 degree to approximately 25 degrees, 0 degree to approximately 30 degrees.

In some embodiments, the array substrate further includes a plurality of dummy bonding pins DBPS and a plurality of dummy central portion vias DCPV. A respective dummy central portion via of the plurality of dummy central portion vias DCPV extends through at least the touch insulating layer TI, exposing at least a portion of a dummy central portion of a plurality of dummy central portions. Optionally, extension directions of the plurality of bonding pins BPS are substantially parallel to extension directions of the plurality of dummy bonding pins DBPS. Optionally, extension directions of the plurality of central portion vias CPV are substantially parallel to extension directions of the plurality of dummy central portion vias DCPV. In some embodiments, a length of a respective bonding pin of the plurality of bonding pins BPS is greater than a length of a respective dummy bonding pin of the plurality of dummy bonding pins DBPS, along an extension direction of the respective bonding pin or an extension direction of the respective dummy bonding pin. In some embodiments, a length of a respective central portion via of the plurality of central portion vias CPV is substantially the same as a length of a respective dummy central portion via of the plurality of dummy central portion vias DCPV, along an extension direction of the respective central portion via or an extension direction of the respective dummy central portion via.

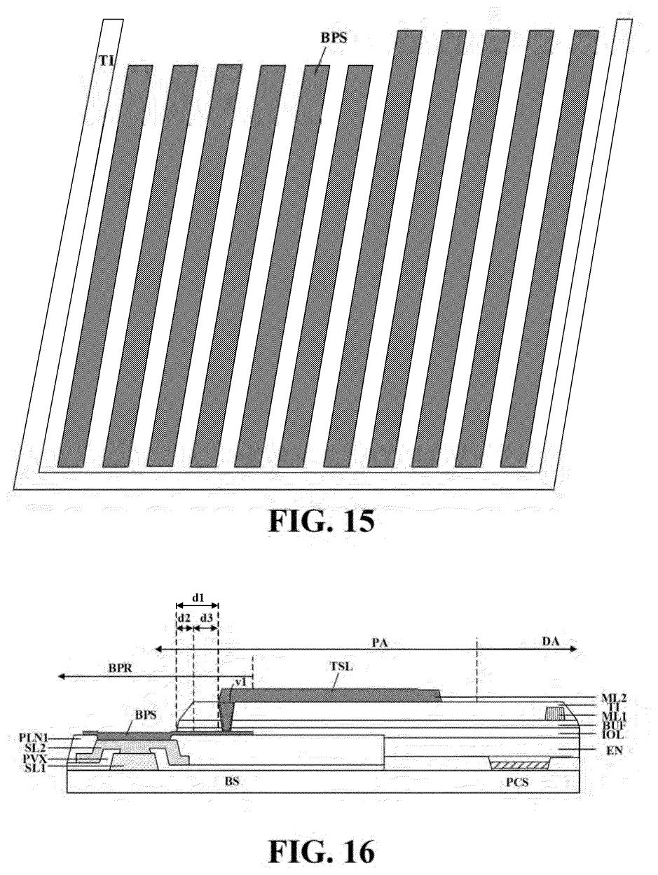

FIG. 14 illustrates a connection between a bonding pin and a touch signal line in a display apparatus in some embodiments according to the present disclosure. FIG. 15 is a plan view of a portion of a display apparatus in a bonding pin region in some embodiments according to the present disclosure. Referring to FIG. 14 and FIG. 15, and FIG. 12, in some embodiments, an orthographic projection of the touch insulating layer TI on a base substrate BS is at least partially (e.g., at least 10%, at least 20%, at least 30%, at least 40%, at least 50%, at least 60%, at least 70%, at least 80%, at least 90%, or at least 95%) non-overlapping with an orthographic projection of the first edge E1 on the base substrate BS. In some embodiments, the orthographic projection of the touch insulating layer TI on the base substrate BS is at least partially (e.g., at least 10%, at least 20%, at least 30%, at least 40%, at least 50%, at least 60%, at least 70%, at least 80%, at least 90%, or at least 95%) non-overlapping with an orthographic projection of the second edge E2 on the base substrate BS. In some embodiments, the orthographic projection of the touch insulating layer TI on the base substrate BS is at least partially (e.g., at least 10%, at least 20%, at least 30%, at least 40%, at least 50%, at least 60%, at least 70%, at least 80%, at least 90%, or at least 95%) non-overlapping with an orthographic projection of the third edge E3 on the base substrate BS. In some embodiments, the orthographic projection of the touch insulating layer TI on the base substrate BS is at least partially (e.g., at least 10%, at least 20%, at least 30%, at least 40%, at least 50%, at least 60%, at least 70%, at least 80%, at least 90%, or at least 95%) non-overlapping with an orthographic projection of the fourth edge E4 on the base substrate BS. In some embodiments, the orthographic projection of the touch insulating layer TI on the base substrate BS is at least partially (e.g., at least 10%, at least 20%, at least 30%, at least 40% e, at least 50%, at least 60%, at least 70%, at least 80%, at least 90, or at least 95%) non-overlapping with an orthographic projection of the central portion CP on the base substrate BS.

In some embodiments, as shown in FIG. 14, an edge Eti of the touch insulating layer TI in the bonding pin region BPR is spaced apart from an exposed surface of a respective bonding pin by a first spacing distance sd1, and is spaced apart from the first via v1 by a second spacing distance sd2. Optionally, the second spacing distance sd2 is greater than the first spacing distance sd1.

In some embodiments, as shown in FIG. 14, the display apparatus includes a plurality of touch signal lines TSL at least partially in the peripheral area PA and a plurality of first vias. A respective touch signal line of the plurality of touch signal lines TSL is connected to a respective bonding pin of the plurality of bonding pins BPS through a first via v1 of the plurality of first vias. Optionally, an exposed surface of the respective bonding pin is spaced apart from the first via v1. Optionally, an orthographic projection of the exposed surface of the respective bonding pin on the base substrate is non-overlapping with an orthographic projection of a portion of the respective touch signal line in the first via v1 on the base substrate.

In some embodiments, as shown in FIG. 15, a portion of the touch insulating layer TI in the bonding pin region BPR is spaced apart from a portion of the touch insulating layer TI in the display area DA.

In alternative embodiments, a portion of the touch insulating layer TI in the bonding pin region BPR is connected to a portion of the touch insulating layer TI in the display area DA. Optionally, the portion of the touch insulating layer TI in the bonding pin region BPR and the portion of the touch insulating layer TI in the display area DA are parts of a unitary structure.

In some embodiments, as shown in FIG. 15, the portion of the touch insulating layer TI in the bonding pin region BPR at least partially surrounds the plurality of bonding pins BPS.

In alternative embodiments, the portion of the touch insulating layer TI in the bonding pin region BPR includes a plurality of teeth respectively extending into a region between adjacent bonding pins of the plurality of bonding pins BPS. In one example, the portion of the touch insulating layer TI in the bonding pin region BPR has a comb shape.

In alternative embodiments, the portion of the touch insulating layer TI in the bonding pin region BPR has a thickness less than a thickness of the portion of the touch insulating layer TI in the display area DA.

In alternative embodiments, the array substrate further includes a portion of the overcoat layer OC on a side of the portion of the touch insulating layer TI in the bonding pin region BPR away from the base substrate.

FIG. 16 illustrates a connection between a bonding pin and a touch signal line in a display apparatus in some embodiments according to the present disclosure. Referring to FIG. 16, in some embodiments, a first distance d1 is equal to or greater than a sum of a second distance d2 and a third distance d3. In some embodiments, the first distance d1 stands for a minimum distance between an orthographic projection of a portion of a respective touch signal line in the first via v1 on a base substrate and an orthographic projection of a position at a portion of a respective bonding pin, where a surface of the portion transitions from being covered by insulating layers to being exposed, on the base substrate. In one example, the insulating layers include the inorganic insulating layer IOL, the buffer layer BUF, and the touch insulating layer TI. The second distance d2 is a minimum distance between the orthographic projection of the position at the portion of a respective bonding pin, where the surface of the portion transitions from being covered by the insulating layers to being exposed, on the base substrate and an orthographic projection of a position at the insulating layers, where a slope angle of the insulating layers covering the portion of the respective bonding pin transition from a positive value to substantially zero, on the base substrate.

In some embodiments, the third distance d3 is greater than a maximum width of the first via v1. By having the third distance d3 greater than the maximum width of the first via v, a safe distance between the first via and an exposed surface of the respective bonding pin can be ensured.

In some embodiments, the third distance d3 stands for a maximum process deviation of the display apparatus. As used herein, the term “process deviation” refers to a difference between a component and its design requirements during the manufacturing process, due to various factors. Process deviation can be caused by factors such as materials, processing techniques, equipment, and environment.

In some embodiments, insulating layers between an exposed surface of the respective bonding pin and the first via v1 comprise a sloped portion (corresponding to d2) and a non-sloped portion (corresponding to d3), as shown in FIG. 16. In some embodiments, a width of the non-sloped portion is greater than a maximum width of the first via v1 along a direction from the exposed surface of the respective bonding pin to the first via v1.

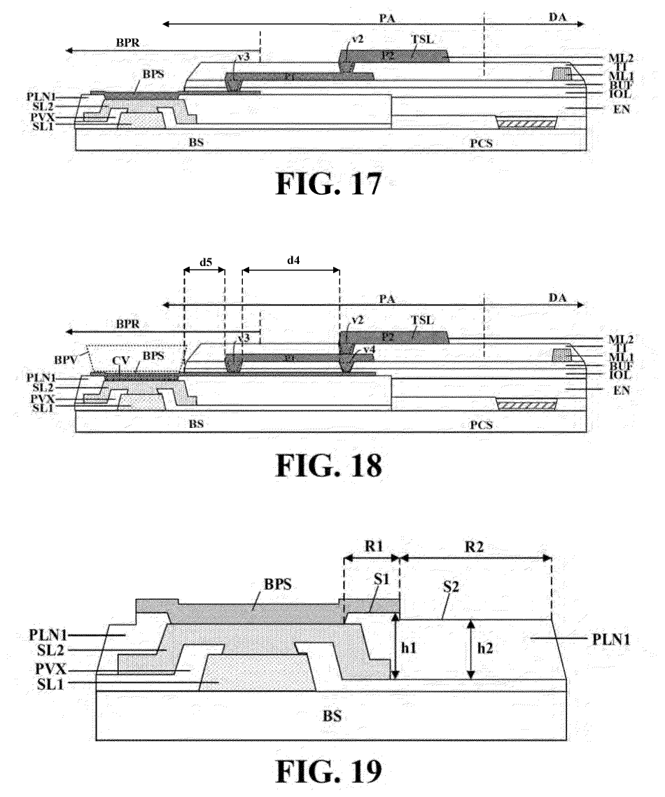

FIG. 17 illustrates a connection between a bonding pin and a touch signal line in a display apparatus in some embodiments according to the present disclosure. Referring to FIG. 17, in some embodiments, the display apparatus in the bonding pin region BPR of the peripheral area PA includes a base substrate BS, a first signal line layer SL1 on the base substrate BS, a passivation layer PVX on a side of the first signal line layer SL1 away from the base substrate BS, a second signal line layer SL2 on a side of the passivation layer PVX away from the first signal line layer SL1, a first planarization layer PLN1 on a side of the second signal line layer 512 away from the passivation layer PVX, and a plurality of bonding pins BPS on a side of the first planarization layer PLN1 away from the second signal line layer SL2.

In some embodiments, the display apparatus includes a plurality of touch signal lines TSL at least partially in the peripheral area PA. In some embodiments, a respective touch signal line of the plurality of touch signal lines TSL includes a first portion P1 and a second portion P2 connected to each other. Optionally, the second portion P2 is connected to a respective bonding pin of the plurality of bonding pins BPS through the first portion P1. Optionally, the first portion P1 is in the first touch layer ML1, and the second portion P2 is in the second touch layer ML2.

In some embodiments, in the peripheral area PA and outside the bonding pin region BPR, the display apparatus includes a base substrate BS, a passivation layer PVX on the base substrate BS, a first planarization layer PLN1 on a side of the passivation layer PVX away from the base substrate BS, an inorganic insulating layer IOL on a side of the first planarization layer PLN1 away from the passivation layer PVX, a buffer layer BUF on a side of the inorganic insulating layer IOL away from the first planarization layer PLN1, a first portion P1 of a respective touch signal line of the plurality of touch signal lines TSL on a side of the buffer layer BUF away from the inorganic insulating layer IOL, a touch insulating layer TI on a side of the first portion P1 away from the buffer layer BUF, and a second portion of the respective touch signal line of the plurality of touch signal line TSL on a side of the touch insulating layer TI away from the first portion P1.

In some embodiments, in the display area DA, the display apparatus includes a pixel driving circuit substrate PCS, a plurality of light emitting elements LE on the pixel driving circuit substrate PCS, an encapsulating layer EN on a side of the plurality of light emitting elements LE away from the pixel driving circuit substrate PCS, an inorganic insulating layer IOL on a side of the encapsulating layer EN away from the plurality of light emitting elements LE, a buffer layer BUF on a side of the inorganic insulating layer IOL away from the encapsulating layer EN, a first touch layer ML1 on a side of the buffer layer BUF away from the inorganic insulating layer IOL, a touch insulating layer TI on a side of the first touch layer ML1 away from the buffer layer BUF, and a second touch layer ML2 on a side of the touch insulating layer TI away from the first touch layer ML1.

In some embodiments, the display apparatus includes a second via v2. The second portion P2 is connected to the first portion P1 through the second via v2. In one example, the second via v2 extends through the touch insulating layer TI.

In some embodiments, the display apparatus further includes a third via v3. The first portion P1 is connected to the respective bonding pin of the plurality of bonding pins BPS through the third via v3. In one example, the third via v3 extends through the buffer layer BUF and the inorganic insulating layer IOL. Optionally, a minimum distance between an exposed surface of the respective bonding pin and the third via v3 is less than a minimum distance between the third via v3 and the second via v2. Optionally, a depth of the second via v2 is greater than a depth of the third via v3. Optionally, a thickness of the touch insulating layer TI is greater than a sum of thicknesses of the inorganic insulating layer IOL and the buffer layer BUF.

In some embodiments, an orthographic projection of the inorganic insulating layer IOL on the base substrate BS at least partially overlaps with an orthographic projection of the plurality of bonding pins BPS on the base substrate BS.

FIG. 18 illustrates a connection between a bonding pin and a touch signal line in a display apparatus in some embodiments according to the present disclosure. Referring to FIG. 18, the display apparatus includes a plurality of touch signal lines TSL at least partially in the peripheral area PA. In some embodiments, a respective touch signal line of the plurality of touch signal lines TSL includes a first portion P1 and a second portion P2 connected to each other. Optionally, the second portion P2 is connected to a respective bonding pin of the plurality of bonding pins BPS through the first portion P1. Optionally, the first portion P1 is in the first touch layer ML1, and the second portion P2 is in the second touch layer ML2.

In some embodiments, the display apparatus includes a second via v2. The second portion P2 is connected to the first portion P1 through the second via v2. In one example, the second via v2 extends through the touch insulating layer TI.

In some embodiments, the display apparatus further includes a third via v3. The first portion P1 is connected to the respective bonding pin of the plurality of bonding pins BPS through the third via v3. In one example, the third via v3 extends through the buffer layer BUF and the inorganic insulating layer IOL.

In some embodiments, the display apparatus further includes a fourth via v4. The first portion P1 is connected to the respective bonding pin of the plurality of bonding pins BPS through the fourth via v4. In one example, the fourth via v4 extends through the buffer layer BUF and the inorganic insulating layer IOL.

In some embodiments, referring to FIG. 18, a fourth distance d4 is greater than the fifth distance d5, wherein the fourth distance d4 stands for a minimum distance between an orthographic projection of a portion of the first portion P1 in the third via v3 on the base substrate and an orthographic projection of a portion of the first portion P1 in the fourth via v4 on the base substrate; and the fifth distance d5 stands for a minimum distance between an orthographic projection of a portion of the first portion P1 in the third via v3 on a base substrate and an orthographic projection of a position at a portion of the respective bonding pin, where a surface of the portion transitions from being covered by insulating layers to being exposed, on the base substrate.

In some embodiments, referring to FIG. 18, the array substrate includes a bonding pin via BPV extending through at least the touch insulating layer TI to expose a surface of a respective bonding pin. Optionally, the array substrate further includes a connecting via CV extending through at least the first planarization layer PLN1, the respective bonding pin connected to the second signal line layer SL2 through the connecting via CV. Optionally, a maximum width of the bonding pin via BPV is greater than a maximum width of the connecting via CV. Optionally, a maximum width of the bonding pin via BPV is greater than a maximum width of the third via v3. Optionally, a maximum width of the bonding pin via BPV is greater than a maximum width of the fourth via v4. Optionally, the bonding pin via BPV, the connecting via CV, the third via v3, and the fourth via v4 are on a side of a contacting interface between the encapsulating layer EN and the first planarization layer PLN1 away from the display area DA.

FIG. 19 illustrates a connection between a bonding pin and a touch signal line in a display apparatus in some embodiments according to the present disclosure. Referring to FIG. 19, in some embodiments, the respective bonding pin of the plurality of bonding pins BPS is in direct contact with the first planarization layer PLN1.

In some embodiments, the first planarization layer PLN1 in a first region R1 is in direct contact with the respective bonding pin, and is not in contact with the respective bonding pin in a second region R2 adjacent to the first region R1. A surface of the first planarization layer PLN1 away from the base substrate BS includes a first part S1 in direct contact with the respective bonding pin and a second part S2 not in contact with the respective bonding pin, the first part S1 and the second part S2 on a same side of the first planarization layer PLN1. A first relative height h1 is greater than a second relative height h2 with respect to a same horizontal plane (e.g., a surface of the passivation layer PVX underneath the first planarization layer PLN1), wherein the first relative height h1 is a height of the first part S1 relative to the same horizontal plane, and the second relative height h2 is a height of the second part S2 relative to the same horizontal plane.

In one example, the respective bonding pin has a thickness substantially the same as a thickness of a touch electrode or touch signal line in the first touch layer ML1. In another example, the first portion P1 has a thickness substantially the same as a thickness of a touch electrode or touch signal line in the first touch layer ML1. As used herein, the term “substantially the same” refers to a difference between two values not exceeding 10% of a base value (e.g., one of the two values), e.g., not exceeding 8%, not exceeding 6%, not exceeding 4%, not exceeding 2%, not exceeding 1%, not exceeding 0.5%, not exceeding 0.1%, not exceeding 0.05%, and not exceeding 0.01%, of the base value.

In an alternative example, the respective bonding pin has a thickness different from a thickness of a touch electrode or touch signal line in the first touch layer ML1.

In another example, the respective bonding pin has a thickness substantially the same as a thickness of a touch electrode or touch signal line in the second touch layer ML2. In another example, the second portion P2 has a thickness substantially the same as a thickness of a touch electrode or touch signal line in the second touch layer ML2.

In an alternative example, the respective bonding pin has a thickness different from a thickness of a touch electrode or touch signal line in the second touch layer ML2.

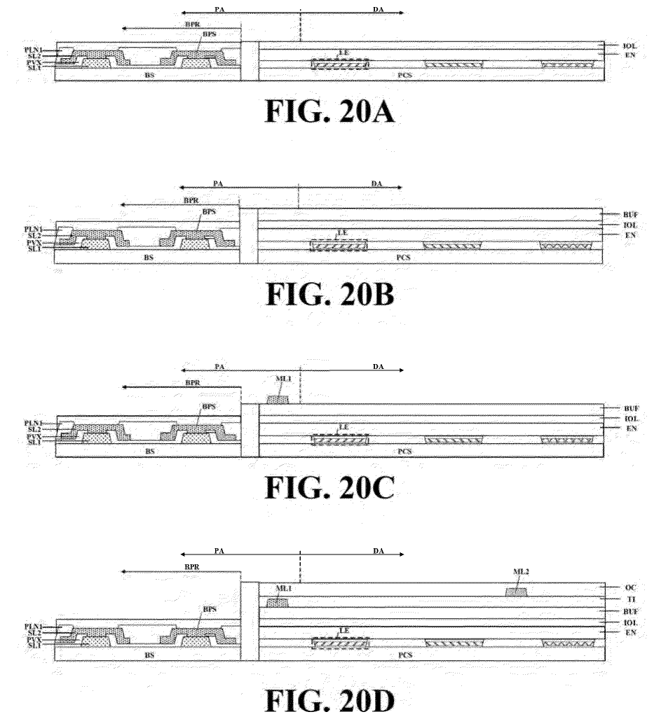

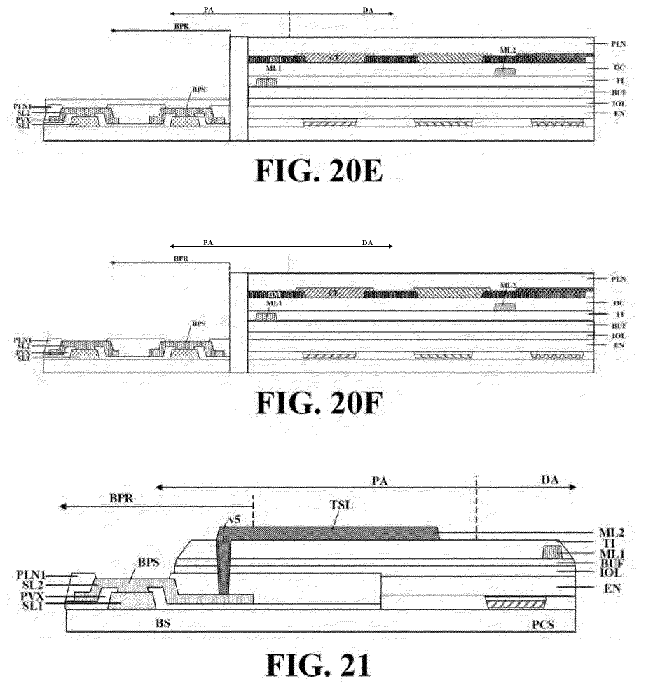

Various appropriate implementations may be practiced according to the present disclosure. FIG. 20A to FIG. 20F illustrates a process of fabricating a display apparatus in some embodiments according to the present disclosure. Referring to FIG. 20A, a plurality of light emitting elements LE are formed in a display area DA of the display apparatus, and an encapsulating layer EN is formed on a side of the plurality of light emitting elements LE away from the pixel driving circuit substrate PCS. In a bonding pin region BPR of the peripheral area PA, a first signal line layer SL1 is formed on a base substrate BS, a passivation layer PVX is formed on a side of the first signal line layer SL1 away from the base substrate BS, and a plurality of bonding pins BPS are formed on a side of the passivation layer PVX away from the base substrate BS. The plurality of bonding pins BPS are formed in a second signal line layer SL2.

In some embodiments, an inorganic insulating layer IOL is formed on a side of the encapsulating layer EN in the display area DA, and on a side of the plurality of bonding pins BPS in the bonding pin region BPR of the peripheral area PA away from a base substrate BS. Subsequent to forming the inorganic insulating layer IOL, the plurality of bonding pins BPS are protected by the inorganic insulating layer IOL from erosion in subsequent fabrication processes.

Referring to FIG. 20B, a buffer layer BUF is formed on a side of the inorganic insulating layer IOL away from the encapsulating layer EN in the display area DA.

Referring to FIG. 20C, a first touch layer ML1 is formed on a side of the buffer layer BUF away from inorganic insulating layer IOL in the display area DA.

Referring to FIG. 20D, in the display area DA, a touch insulating layer TI is formed on a side of the first touch layer ML1 away from the buffer layer BUF, a second touch layer ML2 is formed on a side of the touch insulating layer TI away from the buffer layer BUF, and an overcoat layer OC is formed on a side of the second touch layer ML2 away from touch insulating layer TI. Optionally, the buffer layer BUF, the touch insulating layer TI, and the overcoat layer OC are made of a polymeric organic material.

Referring to FIG. 20E, in the display area DA, a black matrix BM and a color filter CF are formed on a side of the overcoat layer OC away from the touch insulating layer TI, and a planarization layer PLN is formed on a side of the black matrix BM and the color filter CF away from the overcoat layer OC. During this process, as discussed above, alkaline developing solutions are used in patterning the black matrix BM and/or the color filter CF. The plurality of bonding pins BPS in the bonding pin region BPR of the peripheral area PA are covered by the inorganic insulating layer IOL, and are protected from the alkaline developing solutions. The undercut erosion to the plurality of bonding pins BPS can be avoided.

Referring to FIG. 20F, subsequent to forming the black matrix BM and the color filter CF, the inorganic insulating layer IOL in the bonding pin region BPR of the peripheral area PA is at least partially removed, exposing at least a portion of a respective bonding pin of the plurality of bonding pins BPS.

In some embodiments, the display apparatus includes a display area and a peripheral area. In some embodiments, in the display area, the display apparatus includes a pixel driving circuit substrate PCS, a plurality of light emitting elements LE on the pixel driving circuit substrate PCS, an encapsulating layer EN on a side of the plurality of light emitting elements LE away from the pixel driving circuit substrate PCS, an inorganic insulating layer IOL on a side of the encapsulating layer EN away from the plurality of light emitting elements LE, a buffer layer BUF on a side of the inorganic insulating layer IOL away from the encapsulating layer EN, a first touch layer ML1 on a side of the buffer layer BUF away from the inorganic insulating layer IOL, a touch insulating layer TI on a side of the first touch layer ML1 away from the buffer layer BUF, a second touch layer ML2 on a side of the touch insulating layer TI away from the first touch layer ML1, an overcoat layer OC on a side of the second touch layer ML2 away from the touch insulating layer TI, and a black matrix BIM and a color filter CF on a side of the overcoat layer OC away from the second touch layer ML2.

In some embodiments, in the display area, the display apparatus further includes a planarization layer PLN on a side of the black matrix BM and the color filter CF away from the overcoat layer OC.

In some embodiments, the buffer layer BUF, the touch insulating layer TI, and the overcoat layer OC are made of a polymeric organic material.

In some embodiments, in a bonding pin region BPR of the peripheral area PA, the display apparatus includes a base substrate BS, a first signal line layer SL on the base substrate BS, a passivation layer PVX on a side of the first signal line layer SL1 away from the base substrate BS, a plurality of bonding pins BPS in a second signal line layer SL2 on a side of the passivation layer PVX away from the first signal line layer SL1, a first planarization layer PLN1 on a side of the plurality of bonding pins BPS away from the passivation layer PVX.

In some embodiments, the inorganic insulating layer is at least partially absent in the bonding pin region BPR. Optionally, the inorganic insulating layer IOL is completely absent in the bonding pin region BPR. Optionally, an orthographic projection of the inorganic insulating layer IOL on a base substrate is at least partially non-overlapping with (e.g., at least 50% non-overlapping with, at least 60% non-overlapping with, at least 70% non-overlapping with, at least 80% non-overlapping with, at least 90% non-overlapping with, at least 95% non-overlapping with, at least 99% non-overlapping with) an orthographic projection of the plurality of bonding pins BPS on the base substrate. Optionally, the orthographic projection of the inorganic insulating layer IOL on the base substrate is completely non-overlapping with the orthographic projection of the plurality of bonding pins BPS on the base substrate. By having this intricate structure, the plurality of bonding pins BPS remains substantially intact during the fabricating process of the black matrix BM and the color filter CF, avoiding the undercut issue.

FIG. 21 illustrates a connection between a bonding pin and a touch signal line in a display apparatus in some embodiments according to the present disclosure. Referring to FIG. 21, in some embodiments, the display apparatus in the bonding pin region BPR of the peripheral area PA includes a base substrate BS, a first signal line layer SL1 on the base substrate BS, a passivation layer PVX on a side of the first signal line layer SL1 away from the base substrate BS, a plurality of bonding pins BPS in a second signal line layer SL2 on a side of the passivation layer PVX away from the first signal line layer SL1, and a first planarization layer PLN1 on a side of the second signal line layer SL2 away from the passivation layer PVX.

In some embodiments, the display apparatus includes a plurality of touch signal lines TSL at least partially in the peripheral area PA. In some embodiments, in the peripheral area PA and outside the bonding pin region BPR, the display apparatus includes a base substrate BS, a passivation layer PVX on the base substrate BS, a first planarization layer PLN1 on a side of the passivation layer PVX away from the base substrate BS, an inorganic insulating layer IOL on a side of the first planarization layer PLN1 away from the passivation layer PVX, a buffer layer BUF on a side of the inorganic insulating layer IOL away from the first planarization layer PLN1, a touch insulating layer TI on a side of the buffer layer BUF away from the inorganic insulating layer IOL, and a plurality of touch signal line TSL on a side of the touch insulating layer TI away from the buffer layer BUF.

In some embodiments, in the display area DA, the display apparatus includes a pixel driving circuit substrate PCS, a plurality of light emitting elements LE on the pixel driving circuit substrate PCS, an encapsulating layer EN on a side of the plurality of light emitting elements LE away from the pixel driving circuit substrate PCS, an inorganic insulating layer IOL on a side of the encapsulating layer EN away from the plurality of light emitting elements LE, a buffer layer BUF on a side of the inorganic insulating layer IOL away from the encapsulating layer EN, a first touch layer ML1 on a side of the buffer layer BUF away from the inorganic insulating layer IOL, a touch insulating layer TI on a side of the first touch layer ML1 away from the buffer layer BUF, and a second touch layer ML2 on a side of the touch insulating layer TI away from the first touch layer ML1.

In some embodiments, the plurality of touch signal lines TSL are in the second touch layer ML2.

In some embodiments, an orthographic projection of the inorganic insulating layer IOL on the base substrate BS at least partially overlaps with an orthographic projection of the plurality of bonding pins BPS on the base substrate BS. In some embodiments, a respective touch signal line of the plurality of touch signal lines TSL extends through the touch insulating layer TI, the buffer layer BUF, the inorganic insulating layer IOL, and the first planarization layer PLN1 to connect with a respective bonding pin of the plurality of bonding pins BPS. Optionally, the display apparatus includes a fifth via v5. The respective touch signal line of the plurality of touch signal lines TSL is connected to the respective bonding pin of the plurality of bonding pins BPS through the fifth via v5. In one example, the fifth via v5 extends through the touch insulating layer TI, the buffer layer BUF, the inorganic insulating layer IOL, and the first planarization layer PLN1.

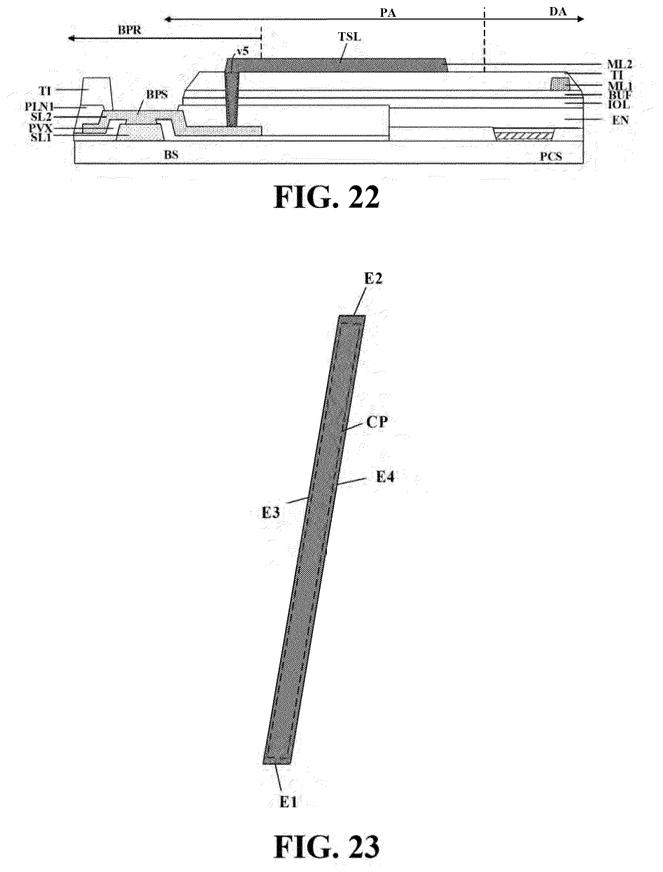

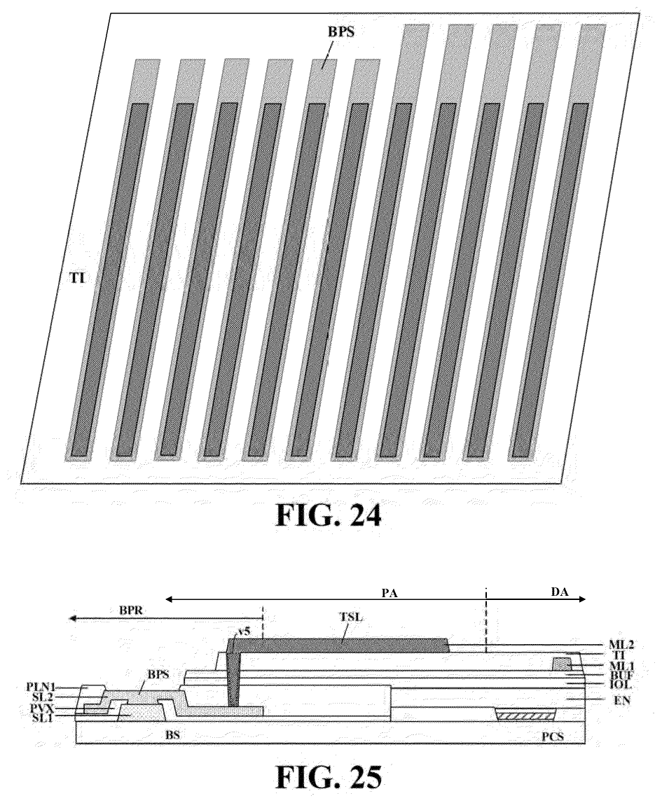

FIG. 22 illustrates a connection between a bonding pin and a touch signal line in a display apparatus in some embodiments according to the present disclosure. FIG. 23 illustrates the structure of a respective bonding pin in a display apparatus in some embodiments according to the present disclosure. FIG. 24 is a plan view of a portion of a display apparatus in a bonding pin region in some embodiments according to the present disclosure. Referring to FIG. 22 to FIG. 24, in some embodiments, the display apparatus in the bonding pin region BPR of the peripheral area PA includes a base substrate BS, a first signal line layer SL1 on the base substrate BS, a passivation layer PVX on a side of the first signal line layer SL1 away from the base substrate BS, a plurality of bonding pins BPS in a second signal line layer SL2 on a side of the passivation layer PVX away from the first signal line layer SL1, a first planarization layer PLN1 on a side of the second signal line layer SL2 away from the passivation layer PVX, and a touch insulating layer TI on a side of the first planarization layer PLN1 away from the plurality of bonding pins BPS.

In some embodiments, the display apparatus includes a plurality of touch signal lines TSL at least partially in the peripheral area PA. In some embodiments, in the peripheral area PA and outside the bonding pin region BPR, the display apparatus includes a base substrate BS, a passivation layer PVX on the base substrate BS, a first planarization layer PLN1 on a side of the passivation layer PVX away from the base substrate BS, an inorganic insulating layer IOL on a side of the first planarization layer PLN1 away from the passivation layer PVX, a buffer layer BUF on a side of the inorganic insulating layer IOL away from the first planarization layer PLN1, a touch insulating layer TI on a side of the buffer layer BUF away from the inorganic insulating layer IOL, and a plurality of touch signal line TSL on a side of the touch insulating layer TI away from the buffer layer BUF.

In some embodiments, in the display area DA, the display apparatus includes a pixel driving circuit substrate PCS, a plurality of light emitting elements LE on the pixel driving circuit substrate PCS, an encapsulating layer EN on a side of the plurality of light emitting elements LE away from the pixel driving circuit substrate PCS, an inorganic insulating layer IOL on a side of the encapsulating layer EN away from the plurality of light emitting elements LE, a buffer layer BUF on a side of the inorganic insulating layer IOL away from the encapsulating layer EN, a first touch layer ML1 on a side of the buffer layer BUF away from the inorganic insulating layer IOL, a touch insulating layer TI on a side of the first touch layer ML1 away from the buffer layer BUF, and a second touch layer ML2 on a side of the touch insulating layer TI away from the first touch layer ML1. In some embodiments, the plurality of touch signal lines TSL are in the second touch layer ML1.

In some embodiments, an orthographic projection of the inorganic insulating layer IOL on the base substrate BS at least partially overlaps with an orthographic projection of the plurality of bonding pins BPS on the base substrate BS. In some embodiments, a respective touch signal line of the plurality of touch signal lines TSL extends through the touch insulating layer TI, the buffer layer BUF, the inorganic insulating layer IOL, and the first planarization layer PLN1 to connect with a respective bonding pin of the plurality of bonding pins BPS. Optionally, the display apparatus includes a fifth via v5. The respective touch signal line of the plurality of touch signal lines TSL is connected to the respective bonding pin of the plurality of bonding pins BPS through the fifth via v5. In one example, the fifth via v5 extends through the touch insulating layer TI, the buffer layer BUF, the inorganic insulating layer IOL, and the first planarization layer PLN1.

In some embodiments, a respective bonding pin of the plurality of bonding pins BPS includes a first edge E1, a second edge E2, a third edge E3, and a fourth edge E4. Optionally, the first edge E1 and the second edge E2 are opposite to each other. Optionally, the third edge E3 and the fourth edge E4 are opposite to each other. The first edge E1 and the second edge E2 are connected through the third edge E3, and are connected through the fourth edge E4. The third edge E3 and the fourth edge E4 are connected through the first edge E1, and are connected through the second edge E2. The first edge E1, the second edge E2, the third edge E3, and the fourth edge E4 surround a central portion CP of the respective bonding pin.

In some embodiments, an orthographic projection of the touch insulating layer TI on a base substrate BS substantially covers (e.g., at least 80% covers, at least 85% covers, at least 90% covers, at least 95% covers, at least 99% covers, or completely covers) an orthographic projection of the first edge E1 on the base substrate BS, substantially covers (e.g., at least 80% covers, at least 85% covers, at least 90% covers, at least 95% covers, at least 99% covers, or completely covers) an orthographic projection of the second edge E2 on the base substrate BS, substantially covers (e.g., at least 80% covers, at least 85% covers, at least 90% covers, at least 95% covers, at least 99% covers, or completely covers) an orthographic projection of the third edge E3 on the base substrate BS, and substantially covers (e.g., at least 80% covers, at least 85% covers, at least 90% covers, at least 95% covers, at least 99% covers, or completely covers) an orthographic projection of the fourth edge E4 on the base substrate BS.

In some embodiments, the orthographic projection of the touch insulating layer TI on the base substrate BS is at least partially (e.g., at least 10%, at least 20%, at least 30%, at least 40%, at least 50%, at least 60%, at least 70%, at least 80%, at least 90%, or at least 95%) non-overlapping with an orthographic projection of the central portion CP of the respective bonding pin on the base substrate BS.

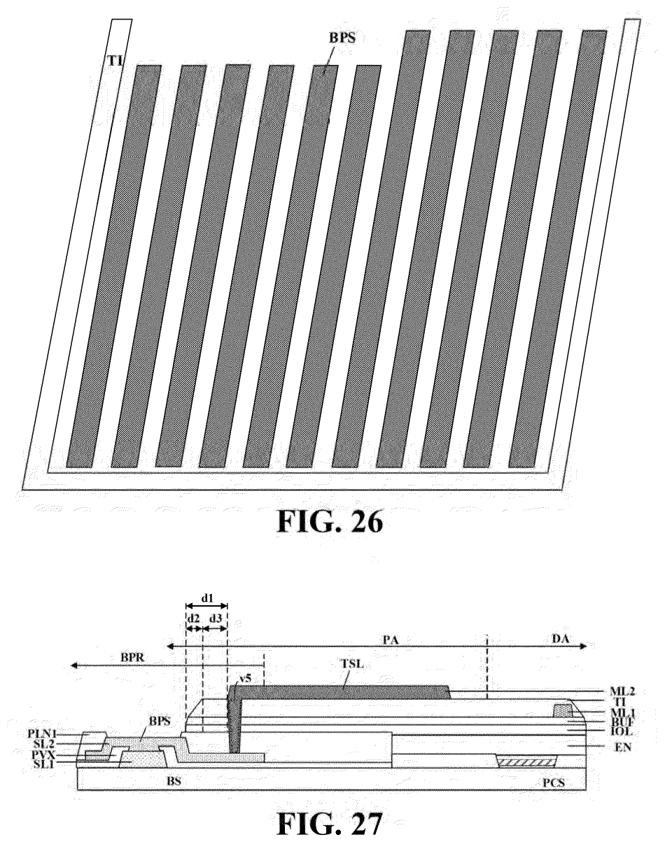

FIG. 25 illustrates a connection between a bonding pin and a touch signal line in a display apparatus in some embodiments according to the present disclosure. FIG. 26 is a plan view of a portion of a display apparatus in a bonding pin region in some embodiments according to the present disclosure. Referring to FIG. 25 and FIG. 26, and FIG. 23, in some embodiments, an orthographic projection of the touch insulating layer TI on a base substrate BS is at least partially (e.g., at least 10%, at least 20%, at least 30%, at least 40%, at least 50%, at least 60%, at least 70%, at least 80%, at least 90%, or at least 95%) non-overlapping with an orthographic projection of the first edge E1 on the base substrate BS. In some embodiments, the orthographic projection of the touch insulating layer TI on the base substrate BS is at least partially (e.g., at least 10%, at least 20%, at least 30%, at least 40%, at least 50%, at least 60%, at least 70%, at least 80%, at least 90%, or at least 95%) non-overlapping with an orthographic projection of the second edge E2 on the base substrate BS. In some embodiments, the orthographic projection of the touch insulating layer TI on the base substrate BS is at least partially (e.g., at least 10%, at least 20%, at least 30%, at least 40%, at least 50%, at least 60%, at least 70%, at least 80%, at least 90%, or at least 95%) non-overlapping with an orthographic projection of the third edge E3 on the base substrate BS. In some embodiments, the orthographic projection of the touch insulating layer TI on the base substrate BS is at least partially (e.g., at least 10%, at least 20%, at least 30%, at least 40%, at least 50%, at least 60%, at least 70%, at least 80%, at least 90%, or at least 95%) non-overlapping with an orthographic projection of the fourth edge E4 on the base substrate BS. In some embodiments, the orthographic projection of the touch insulating layer TI on the base substrate BS is at least partially (e.g., at least 10%, at least 20%, at least 30%, at least 40%, at least 50%, at least 60/o, at least 70%, at least 80%, at least 90%, or at least 95%) non-overlapping with an orthographic projection of the central portion CP on the base substrate BS.

FIG. 27 illustrates a connection between a bonding pin and a touch signal line in a display apparatus in some embodiments according to the present disclosure. Referring to FIG. 27, in some embodiments, a first distance d1 is equal to or greater than a sum of a second distance d2 and a third distance d3. In some embodiments, the first distance d1 stands for a minimum distance between an orthographic projection of a portion of a respective touch signal line in the fifth via v5 on a base substrate and an orthographic projection of a position at a portion of a respective bonding pin, where a surface of the portion transitions from being covered by insulating layers to being exposed, on the base substrate. In one example, the insulating layers include the inorganic insulating layer IOL, the buffer layer BLF, the touch insulating layer TI, and the first planarization layer PLN1. The second distance d2 is a minimum distance between the orthographic projection of the position at the portion of a respective bonding pin, where the surface of the portion transitions from being covered by the insulating layers to being exposed, on the base substrate and an orthographic projection of a position at the insulating layers, where a slope angle of the insulating layers covering the portion of the respective bonding pin transition from a positive value to substantially zero, on the base substrate. The third distance d3 stands for a maximum process deviation of the display apparatus. As used herein, the term “process deviation” refers to a difference between a component and its design requirements during the manufacturing process, due to various factors. Process deviation can be caused by factors such as materials, processing techniques, equipment, and environment.

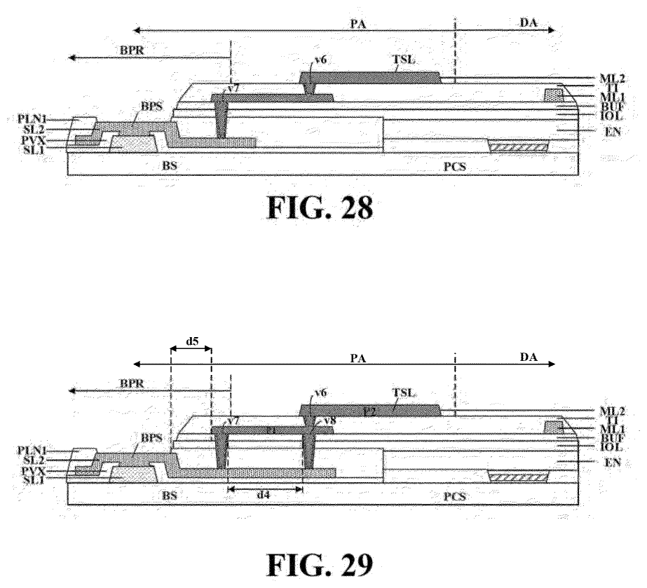

FIG. 28 illustrates a connection between a bonding pin and a touch signal line in a display apparatus in some embodiments according to the present disclosure. Referring to FIG. 28, in some embodiments, the display apparatus in the bonding pin region BPR of the peripheral area PA includes a base substrate BS, a first signal line layer SL1 on the base substrate BS, a passivation layer PVX on a side of the first signal line layer SL1 away from the base substrate BS, a plurality of bonding pins BPS in a second signal line layer SL2 on a side of the passivation layer PVX away from the first signal line layer SL1, and a first planarization layer PLN1 on a side of the second signal line layer SL2 away from the passivation layer PVX.

In some embodiments, the display apparatus includes a plurality of touch signal lines TSL at least partially in the peripheral area PA. In some embodiments, a respective touch signal line of the plurality of touch signal lines TSL includes a first portion P1 and a second portion P2 connected to each other. Optionally, the second portion P2 is connected to a respective bonding pin of the plurality of bonding pins BPS through the first portion P1. Optionally, the first portion P1 is in the first touch layer ML1, and the second portion P2 is in the second touch layer ML2.

In some embodiments, in the peripheral area PA and outside the bonding pin region BPR, the display apparatus includes a base substrate BS, a passivation layer PVX on the base substrate BS, a first planarization layer PLN1 on a side of the passivation layer PVX away from the base substrate BS, an inorganic insulating layer IOL on aside of the first planarization layer PLN1 away from the passivation layer PVX, a buffer layer BUF on a side of the inorganic insulating layer 101 away from the first planarization layer PLN1, a first portion Pt of a respective touch signal line of the plurality of touch signal lines TSL on a side of the buffer layer BUF away from the inorganic insulating layer IOL, a touch insulating layer TI on a side of the first portion P1 away from the buffer layer BUF, and a second portion of the respective touch signal line of the plurality of touch signal line TSL on a side of the touch insulating layer TI away from the first portion P1.

In some embodiments, in the display area DA, the display apparatus includes a pixel driving circuit substrate PCS, a plurality of light emitting elements LE on the pixel driving circuit substrate PCS, an encapsulating layer EN on a side of the plurality of light emitting elements LE away from the pixel driving circuit substrate PCS, an inorganic insulating layer IOL on a side of the encapsulating layer EN away from the plurality of light emitting elements LE, a buffer layer BUF on a side of the inorganic insulating layer IOL away from the encapsulating layer EN, a first touch layer ML1 on a side of the buffer layer BUF away from the inorganic insulating layer IOL, a touch insulating layer TI on a side of the first touch layer ML1 away from the buffer layer BUF, and a second touch layer ML2 on a side of the touch insulating layer TI away from the first touch layer ML1.

In some embodiments, the display apparatus includes a sixth via v6. The second portion P2 is connected to the first portion P1 through the sixth via v6. In one example, the sixth via v6 extends through the touch insulating layer TI.

In some embodiments, the display apparatus further includes a seventh via v7. The first portion P1 is connected to the respective bonding pin of the plurality of bonding pins BPS through the seventh via v7. In one example, the seventh via v7 extends through the buffer layer BUF, the inorganic insulating layer IOL, and the first planarization layer PLN1.

In some embodiments, an orthographic projection of the inorganic insulating layer IOL on the base substrate BS at least partially overlaps with an orthographic projection of the plurality of bonding pins BPS on the base substrate BS.

FIG. 29 illustrates a connection between a bonding pin and a touch signal line in a display apparatus in some embodiments according to the present disclosure. Referring to FIG. 29, the display apparatus includes a plurality of touch signal lines TSL at least partially in the peripheral area PA. In some embodiments, a respective touch signal line of the plurality of touch signal lines TSL includes a first portion P1 and a second portion P2 connected to each other. Optionally, the second portion P2 is connected to a respective bonding pin of the plurality of bonding pins BPS through the first portion P1. Optionally, the first portion P1 is in the first touch layer ML1, and the second portion P2 is in the second touch layer ML2.

In some embodiments, the display apparatus includes a sixth via v6. The second portion P2 is connected to the first portion P1 through the sixth via v6. In one example, the sixth via v6 extends through the touch insulating layer TI.

In some embodiments, the display apparatus further includes a seventh via v7. The first portion P1 is connected to the respective bonding pin of the plurality of bonding pins BPS through the seventh via v7. In one example, the third via v3 extends through the buffer layer BUF, the inorganic insulating layer IOL, and the first planarization layer PLN1.

In some embodiments, the display apparatus further includes an eighth via v8. The first portion P1 is connected to the respective bonding pin of the plurality of bonding pins BPS through the eighth via v8. In one example, the eighth via v8 extends through the buffer layer BUF, the inorganic insulating layer IOL, and the first planarization layer PLN1.

In some embodiments, referring to FIG. 29, a fourth distance d4 is greater than the fifth distance d5, wherein the fourth distance d4 stands for a minimum distance between an orthographic projection of a portion of the first portion P1 in the seventh via v7 on the base substrate and an orthographic projection of a portion of the first portion P1 in the eighth via v8 on the base substrate; and the fifth distance d5 stands for a minimum distance between an orthographic projection of a portion of the first portion P1 in the seventh via v7 on a base substrate and an orthographic projection of a position at a portion of the respective bonding pin BPS, where a surface of the portion transitions from being covered by insulating layers to being exposed, on the base substrate.

In another aspect, the present disclosure further provides a method of fabricating a display apparatus having a display area and a peripheral area. The peripheral area includes a bonding pin region. In some embodiments, the method includes, in the display area, forming a pixel driving circuit substrate, forming a plurality of light emitting elements on the pixel driving circuit substrate, and forming an encapsulating layer on a side of the plurality of light emitting elements away from the pixel driving circuit substrate.

In some embodiments, the method further includes, in the bonding pin region of the peripheral area, forming a plurality of bonding pins.

In some embodiments, the method further includes forming an inorganic insulating layer on a side of the encapsulating layer in the display area, and on a side of the plurality of bonding pins in the bonding pin region of the peripheral area away from a base substrate.

In some embodiments, the method further includes, in the display area, forming a buffer layer on a side of the inorganic insulating layer away from the encapsulating layer, forming a first touch layer on a side of the buffer layer away from inorganic insulating layer, forming a touch insulating layer on a side of the first touch layer away from the buffer layer, forming a second touch layer on a side of the touch insulating layer away from the buffer layer, forming an overcoat layer on a side of the second touch layer away from touch insulating layer, and forming a black matrix and a color filter on a side of the overcoat layer away from the touch insulating layer. Optionally, the buffer layer, the touch insulating layer, and the overcoat layer are formed using a polymeric organic material.

In some embodiments, the method further includes at least partially removing a portion of the inorganic insulating layer in the bonding pin region to expose at least a portion of a respective bonding pin of the plurality of bonding pins.

In some embodiments, the method further includes, in the bonding pin region, forming a first signal line layer on the base substrate; forming a passivation layer on a side of the first signal line layer away from the base substrate; forming a second signal line layer on a side of the passivation layer away from the first signal line layer; forming a first planarization layer on a side of the second signal line layer away from the passivation layer; and forming the plurality of bonding pins on a side of the first planarization layer away from the second signal line layer.

In some embodiments, the method further includes, in the bonding pin region, forming a first signal line layer on the base substrate; forming a passivation layer on a side of the first signal line layer away from the base substrate; forming the plurality of bonding pins in a second signal line layer on a side of the passivation layer away from the first signal line layer; and forming a first planarization layer on a side of the second signal line layer away from the passivation layer.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A display apparatus, comprising a display area and a peripheral area;
wherein, in the display area, the display apparatus comprises a pixel driving circuit substrate, a plurality of light emitting elements on the pixel driving circuit substrate, an encapsulating layer on a side of the plurality of light emitting elements away from the pixel driving circuit substrate; and an inorganic insulating layer on a side of the encapsulating layer away from the plurality of light emitting elements;
in a bonding pin region of the peripheral area, the display apparatus comprises a base substrate, a plurality of bonding pins on the base substrate; and
an orthographic projection of the inorganic insulating layer on the base substrate is at least partially non-overlapping with an orthographic projection of the plurality of bonding pins on the base substrate.

2. The display apparatus of claim 1, in the display area, further comprising:
a buffer layer on a side of the inorganic insulating layer away from the encapsulating layer;
a first touch layer on a side of the buffer layer away from the inorganic insulating layer;
a touch insulating layer on a side of the first touch layer away from the buffer layer;
a second touch layer on a side of the touch insulating layer away from the first touch layer; and
an overcoat layer on a side of the second touch layer away from the touch insulating layer;
wherein the buffer layer, the touch insulating layer, and the overcoat layer are made of a polymeric organic material.

3. The display apparatus of claim 2, in the display area, further comprising a black matrix and a color filter on a side of the overcoat layer away from the second touch layer;
wherein the black matrix and the color filter are in direct contact with the overcoat layer.

4. The display apparatus of claim 1, wherein the orthographic projection of the inorganic insulating layer on the base substrate is completely non-overlapping with the orthographic projection of the plurality of bonding pins on the base substrate.

5. The display apparatus of claim 1, further comprising a plurality of touch signal lines at least partially in the peripheral area;
wherein a respective touch signal line of the plurality of touch signal lines extends through at least a touch insulating layer, a buffer layer, and the inorganic insulating layer to connect with a respective bonding pin of the plurality of bonding pins;
the respective touch signal line is at least partially in a second touch layer.

6. The display apparatus of claim 5, wherein the respective bonding pin comprises a first edge, a second edge, a third edge, and a fourth edge;
an orthographic projection of the touch insulating layer on the base substrate substantially covers an orthographic projection of the first edge on the base substrate, substantially covers an orthographic projection of the second edge on the base substrate, substantially covers an orthographic projection of the third edge on the base substrate, and substantially covers an orthographic projection of the fourth edge on the base substrate;
the first edge, the second edge, the third edge, and the fourth edge surround a central portion of the respective bonding pin; and
the orthographic projection of the touch insulating layer on the base substrate is at least partially non-overlapping with an orthographic projection of the central portion of the respective bonding pin on the base substrate.

7. The display apparatus of claim 5, wherein the respective bonding pin comprises a first edge, a second edge, a third edge, and a fourth edge;
an orthographic projection of the touch insulating layer on the base substrate is at least partially non-overlapping with an orthographic projection of the first edge on the base substrate, is at least partially non-overlapping with an orthographic projection of the second edge on the base substrate, is at least partially non-overlapping with an orthographic projection of the third edge on the base substrate, and is at least partially non-overlapping with an orthographic projection of the fourth edge on the base substrate;
the first edge, the second edge, the third edge, and the fourth edge surround a central portion of the respective bonding pin; and
the orthographic projection of the touch insulating layer on the base substrate is at least partially non-overlapping with an orthographic projection of the central portion of the respective bonding pin on the base substrate.

8. The display apparatus of claim 5, further comprising a first via;
wherein the respective touch signal line is connected to the respective bonding pin through the first via;
insulating layers between an exposed surface of the respective bonding pin and the first via comprise a sloped portion and a non-sloped portion;
a width of the non-sloped portion is greater than a maximum width of the first via along a direction from the exposed surface of the respective bonding pin to the first via.

9. The display apparatus of claim 5, further comprising a second via and a third via;
wherein the respective touch signal line comprises a first portion in a first touch layer and a second portion in a second touch layer;
the second portion is connected to the first portion through the second via; and
the first portion is connected to the respective bonding pin through the third via.

10. The display apparatus of claim 5, further comprising a second via, a third via, and a fourth via;
wherein the respective touch signal line comprises a first portion in a first touch layer and a second portion in a second touch layer;
the second portion is connected to the first portion through the second via;
the first portion is connected to the respective bonding pin through the third via, and through the fourth via, respectively.

11. The display apparatus of claim 10, wherein a fourth distance is greater than a fifth distance;
the fourth distance stands for a minimum distance between an orthographic projection of a portion of the first portion in the third via on the base substrate and an orthographic projection of a portion of the first portion in the fourth via on the base substrate; and
the fifth distance stands for a minimum distance between an orthographic projection of a portion of the first portion in the third via on the base substrate and an orthographic projection of a position at a portion of the respective bonding pin, where a surface of the portion transitions from being covered by insulating layers to being exposed, on the base substrate.

12. The display apparatus of claim 5, further comprising a first via;
wherein the respective touch signal line is connected to the respective bonding pin through the first via; and
the first via extends through the touch insulating layer, the buffer layer, and the inorganic insulating layer.

13. The display apparatus of claim 5, further comprising a fifth via;
wherein the respective touch signal line is connected to the respective bonding pin through the fifth via; and
the fifth via extends through the touch insulating layer, the buffer layer, the inorganic insulating layer, and a first planarization layer.

14. The display apparatus of claim 1, in the peripheral area, further comprising a first voltage supply line configured to provide a first voltage supply signal to the display area and a second voltage supply line configured to provide a second voltage supply signal to the display area;
wherein an orthographic projection of at least one of the first voltage supply line or the second voltage supply line on the base substrate at least partially overlaps with an orthographic projection of the plurality of bonding pins on the base substrate.

15. The display apparatus of claim 1, wherein, in the bonding pin region of the peripheral area, the display apparatus comprises:
a first signal line layer on the base substrate;
a passivation layer on a side of the first signal line layer away from the base substrate;
a second signal line layer on a side of the passivation layer away from the first signal line layer;
a first planarization layer on a side of the second signal line layer away from the passivation layer; and
the plurality of bonding pins on a side of the first planarization layer away from the second signal line layer.

16. The display apparatus of claim 15, wherein a respective bonding pin of the plurality of bonding pins is in direct contact with the first planarization layer;
the first planarization layer in a first region is in direct contact with the respective bonding pin, and is not in contact with the respective bonding pin in a second region adjacent to the first region;
a surface of the first planarization layer away from the base substrate includes a first part in direct contact with the respective bonding pin and a second part not in contact with the respective bonding pin, the first part and the second part being on a same side of the first planarization layer;
a first relative height is greater than a second relative height with respect to a same horizontal plane;
the first relative height is a height of the first part relative to the same horizontal plane; and
the second relative height is a height of the second part relative to the same horizontal plane.

17. The display apparatus of claim 1, wherein, in the bonding pin region of the peripheral area, the display apparatus comprises:
a first signal line layer on the base substrate;
a passivation layer on a side of the first signal line layer away from the base substrate;
the plurality of bonding pins in a second signal line layer on a side of the passivation layer away from the first signal line layer; and
a first planarization layer on a side of the second signal line layer away from the passivation layer.

18. A method of fabricating a display apparatus having a display area and a peripheral area, the peripheral area comprising a bonding pin region;
wherein the method comprises:
in the display area, forming a pixel driving circuit substrate, forming a plurality of light emitting elements on the pixel driving circuit substrate, and forming an encapsulating layer on a side of the plurality of light emitting elements away from the pixel driving circuit substrate;
in the bonding pin region, forming a plurality of bonding pins;
forming an inorganic insulating layer on a side of the encapsulating layer in the display area, and on a side of the plurality of bonding pins in the bonding pin region of the peripheral area away from the base substrate;
subsequent to forming the inorganic insulating layer, in the display area, forming a black matrix and a color filter on a side of the plurality of light emitting elements away from the pixel driving circuit substrate; and
subsequent to forming the black matrix and the color filter, at least partially removing a portion of the inorganic insulating layer in the bonding pin region to expose at least a portion of a respective bonding pin of the plurality of bonding pins.

19. The method of claim 18, further comprising, in the bonding pin region:
forming a first signal line layer on the base substrate;
forming a passivation layer on a side of the first signal line layer away from the base substrate;
forming a second signal line layer on a side of the passivation layer away from the first signal line layer;
forming a first planarization layer on a side of the second signal line layer away from the passivation layer; and
forming the plurality of bonding pins on a side of the first planarization layer away from the second signal line layer.

20. A display apparatus, comprising a display area and a peripheral area;
wherein, in the display area, the display apparatus comprises a pixel driving circuit substrate, a plurality of light emitting elements on the pixel driving circuit substrate, an encapsulating layer on a side of the plurality of light emitting elements away from the pixel driving circuit substrate, an inorganic insulating layer on a side of the encapsulating layer away from the plurality of light emitting elements;
in a bonding pin region of the peripheral area, the display apparatus comprises a base substrate, a plurality of bonding pins on the base substrate; and
an orthographic projection of the inorganic insulating layer on the base substrate is at least partially non-overlapping with an orthographic projection of the plurality of bonding pins on the base substrate;
wherein the display apparatus further comprises:
a plurality of touch signal lines at least partially in the peripheral area; and
a plurality of first vias;
wherein the respective touch signal line is connected to a respective bonding pin of the plurality of bonding pins through a first via of the plurality of first vias; and
an exposed surface of the respective bonding pin is spaced apart from the first via.
